(19) United States
(12) Patent Application Publication
(10) Pub. No.: US 2013/0087682 A1
(43) Pub. Date: Apr. 11, 2013

(54) PHOTOELECTRIC CONVERSION DEVICE, IMAGING DEVICE, AND METHOD FOR DRIVING PHOTOELECTRIC CONVERSION DEVICE

(71) Applicant: FUJIFILM CORPORATION, Tokyo (JP)

(72) Inventor: Kimiatsu NOMURA, Kanagawa (JP)

(73) Assignee: FUJIFILM CORPORATION, Tokyo (JP)

(21) Appl. No.: 13/687,950

(22) Filed: Nov. 28, 2012

Related U.S. Application Data
(63) Continuation of application No. PCT/JP2011/061663, filed on May 20, 2011.

(30) Foreign Application Priority Data
May 31, 2010 (JP) 2010-125325

(51) Int. Cl. H01L 51/44

(52) U.S. Cl. CPC H01L 51/44
USPC 250/206; 257/40

(57) ABSTRACT

A photoelectric conversion device includes, in the following order: a first electrode; an electron blocking layer; a photoelectric conversion layer containing a merocyanine dye; a hole blocking layer; and a transparent electrode as a second electrode, and an absorption maximum wavelength in a thin film absorption spectrum of the photoelectric conversion layer containing a merocyanine dye is within a range of from 400 to 520 nm.

### TECHNICAL FIELD

The present invention relates to a photoelectric conversion device, an imaging device provided with a photoelectric conversion device, and a method for driving a photoelectric conversion device.

### BACKGROUND ART

As for solid-state imaging devices, there is widely used a flat light-receiving device in which photoelectric conversion sites are two-dimensionally arrayed in a semiconductor to form a pixel, and a signal generated by photoelectric conversion in each pixel is charge-transferred and read out according to a CCD circuit or a CMOS circuit. As for conventional photoelectric conversion sites, those in which a photodiode part using PN junction is formed in a semiconductor such as Si are generally used.

In recent years, with the progress of a multi-pixel system, the pixel size becomes small, and the area of the photodiode part becomes small. This brings about a reduction in an aperture ratio and a reduction in light collection efficiency, resulting in a problem of reduction in sensitivity. As for a technique for enhancing the aperture ratio and the like, studies are being made on a solid-state imaging device having an organic photoelectric conversion layer using an organic material.

As for a method for solving these problems, it may be considered to stack photoelectric conversion parts capable of detecting different light wavelengths in the vertical direction to the semiconductor substrate surface. As for such solid-state imaging devices, in the case of limiting to visible light, for example, Patent Document 1 discloses a solid-state imaging device in which a plurality of photoelectric conversion parts are formed in a stacked structure in the depth direction of the semiconductor substrate while utilizing the wavelength dependency of a light absorption coefficient of Si, thereby separating colors by a difference in the depth of the respective photoelectric conversion parts. In addition, Patent Document 2 discloses an imaging device in which an organic photoelectric conversion layer is stacked above the semiconductor substrate. However, so far as the difference in the depth direction of Si is concerned, there is originally involved such another problem that the absorption range is overlapped among the respective portions, and spectral characteristics are bad, and therefore, the color separation is poor.

In addition, there have hitherto been some known examples regarding a photoelectric conversion device, an imaging device, and a photosensor each using an organic photoelectric conversion layer. Then, in particular, high photoelectric conversion efficiency (exciton dissociation efficiency and charge transporting properties) and low dark current (amount of dark time carrier) are considered to be a problem. As for improvement methods thereof, there are disclosed introduction of a pn-junction or introduction of a bulk-heterostructure for the former and introduction of a blocking layer or the like for the latter.

For an enhancement of the photoelectric conversion efficiency and a reduction of the dark current, though structural improvement methods thereof are large in the effects, characteristics of the material to be used greatly contribute to the device performance, too. In addition, for the purpose of improving the sensitivity that is an important problem of the organic photoelectric conversion device (in particular, the application as an imaging device or a photosensor), Patent Documents 3 and 4 disclose the use of a merocyanine dye as an organic material (semiconductor), but a problem regarding the photoselection still remains. In the case where the photoselection is low, a color mixing ratio as the device performance is deteriorated. Ideally, it is preferable that photoelectric conversion devices of R light, G light, and B light have sensitivities of zero against G light and B light, R light and B light, and R light and G light, respectively. However, as for an actual problem, it is a problem that even an R light photoelectric conversion device has sensitivity against G light and R light, even a G light photoelectric conversion device has sensitivity against R light and B light, and even a B light photoelectric conversion device has sensitivity against R light and R light, respectively. When relative sensitivities against G light and B light, R light and B light, and R light and G light relative to the sensitivities of the R light, G light and B light photoelectric conversion devices are defined as the color mixing ratio, the color mixing ratio is desirably low as far as possible. In the case where the color mixing ratio is high, since deviations of output signals of the actual devices are large relative to ideal RGB signals corresponding to object light, the color reproduction ability of object light is deteriorated. Accordingly, it is extremely important that the photoelectric conversion device has high photoselection, namely a low color mixing ratio. Incidentally, the R light, the G light, and the B light as referred to in this specification mean red light, green light, and blue light, respectively.

### PRIOR ART DOCUMENTS

### Patent Documents

Patent Document 1: U.S. Pat. No. 5,965,875
Patent Document 2: JP-A-2003-332551
Patent Document 3: JP-A-2009-135318
Patent Document 4: JP-A-2006-86160

### SUMMARY OF THE INVENTION

### Problem to be Solved by the Invention

In the case of using a photoelectric conversion device as a solid-state imaging device, it is required that high photoelectric conversion efficiency (high sensitivity) and low dark current are satisfied, and that high photoselection is revealed. However, what kind of organic photoelectric conversion materials or device structures may give such performances have not been specifically disclosed yet.

Furthermore, in order to realize an organic photoelectric conversion device of a three-layer stack type, organic photoelectric conversion devices selectively having spectral sensitivity to red light, green light, and blue light, respectively are required, and devices with more excellent photoselection, which are capable of exhibiting a low color mixing ratio, are demanded.

An object of the invention is to provide a photoelectric conversion device exhibiting high photoelectric conversion efficiency (high sensitivity) and low dark current and having high photoselection against B light for the purpose of exhibiting a low color mixing ratio (within a range where an absorption maximum wavelength in a thin film absorption spectrum of the photoelectric conversion layer is from 400 to 520 nm), an imaging device provided with the subject photoelectric conversion device, and a method for driving the subject photoelectric conversion device.

### Means for Solving the Problem

The foregoing problem of the invention has been solved by the following dissolution means.

[1] A photoelectric conversion device comprising a first electrode, an electron blocking layer, a photoelectric conversion layer containing a merocyanine dye, a hole blocking layer, and a transparent electrode as a second electrode in this order, wherein an absorption maximum wavelength in a thin film absorption spectrum of the photoelectric conversion layer containing a merocyanine dye falls within the range of from 400 to 520 nm.
[2] The photoelectric conversion device as set forth in [1], wherein the merocyanine dye is represented by the following general formula (1):

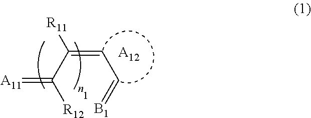

wherein A₁₁ represents a heterocyclic ring; n₁ represents an integer of from 0 to 2; A₁₂ represents a heterocyclic ring containing an sp2 carbon atom and a carbon atom of a carbonyl group or a thiocarbonyl group; each of R₁₁ and R₁₂ independently represents a hydrogen atom or a substituent; and B₁ represents an oxygen atom or a sulfur atom.
[3] The photoelectric conversion device as set forth in [2], wherein A₁₂ in the general formula (1) is a 6-membered heterocyclic ring.
[4] The photoelectric conversion device as set forth in [2] or [3], wherein an absorption maximum wavelength of the merocyanine dye represented by the general formula (1) in a solution state in a visible region falls within the range of from 400 to 500 nm.
[5] The photoelectric conversion device as set forth in any one of [1] to [4], wherein the first electrode is a transparent electrode.
[6] The photoelectric conversion device as set forth in any one of [1] to [5], wherein the electron blocking layer contains an organic electron blocking material.
[7] The photoelectric conversion device as set forth in any one of [1] to [6], wherein the hole blocking layer contains an inorganic material.
[8] An imaging device provided with the photoelectric conversion device as set forth in any one of [1] to [7].
[9] A method for driving the photoelectric conversion device as set forth in any one of [1] to [7] or the photoelectric conversion device provided in the imaging device as set forth in [8], wherein an electric field of 1×10⁻⁴ V/cm or more and not more than 1×10⁷ V/cm is impressed between the electrodes of the photoelectric conversion device.

### Effect of the Invention

According to the invention, a photoelectric conversion device exhibiting high photoelectric conversion efficiency (high sensitivity) and low dark current and having high photoselection, an imaging device provided with the subject photoelectric conversion device, and a method for driving the subject photoelectric conversion device are obtainable.

### BRIEF DESCRIPTION OF THE DRAWINGS

Each of FIG. 1A, FIG. 1B, and FIG. 1C is a schematic cross-sectional view of a photoelectric conversion device, and FIG. 1C is a schematic cross-sectional view of a photoelectric conversion device according to a first embodiment of the invention.

FIG. 2 is a schematic cross-sectional view of an imaging device according to a second embodiment of the invention.

FIG. 3 is a schematic cross-sectional view of an imaging device according to a third embodiment of the invention.

FIG. 4 is a schematic cross-sectional view of an imaging device according to a fourth embodiment of the invention.

FIG. 5 is a schematic partial surface view of an imaging device according to a fifth embodiment of the invention.

FIG. 6 is a schematic cross-sectional view of an X-X line position of FIG. 5.

### MODES FOR CARRYING OUT THE INVENTION

The invention is hereunder described in detail.

The photoelectric conversion device according to the invention is a photoelectric conversion device comprising a first electrode, an electron blocking layer, a photoelectric conversion layer containing a merocyanine dye, a hole blocking layer, and a transparent electrode as a second electrode in this order, wherein an absorption maximum wavelength in a thin film absorption spectrum of the photoelectric conversion layer containing a merocyanine dye falls within the range of from 400 to 520 nm

### [Organic Photoelectric Conversion Dye]

The photoelectric conversion layer according to the invention contains a merocyanine dye. An organic photoelectric conversion dye other than the merocyanine dye may be further contained. In addition, the photoelectric conversion device according to the invention may further comprise a photoelectric conversion layer containing an organic photoelectric conversion dye other than the merocyanine dye.

As for the organic photoelectric conversion dye other than the merocyanine dye, coloring matters (dyes or pigments) that are a compound having an HOMO level shallower than an HOMO level of a fullerene and an LUMO level shallower than an LUMO level of a fullerene and having an absorption peak in a visible region (wavelength: 400 nm to 700 nm) may be useful. Examples thereof include an arylidene compound, a squarylium compound, a coumarin compound, an azo based compound, a porphyrin compound, a quinacridone compound, an anthraquinone compound, a phthalocyanine compound, an indigo compound, and a diketopyrrolopyrole compound.

### (Merocyanine Dye)

The merocyanine dye is described. In the photoelectric conversion device according to the invention, the absorption maximum wavelength in a thin film absorption spectrum of the photoelectric conversion layer containing a merocyanine dye falls within the range of from 400 to 520 nm, preferably from 400 to 510 nm, and especially preferably from 400 to 500 nm. By allowing the absorption maximum wavelength to fall within the foregoing range, the photoselection against B light increases. Though the merocyanine dye which is used in the invention is not particularly limited so far as it may make the absorption maximum wavelength fall within the range of from 400 to 520 nm, it is preferably a dye represented by the following general formula (1).

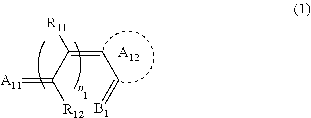

In the general formula (1), A₁₁ represents a heterocyclic ring; n₁ represents an integer of from 0 to 2; A₁₂ represents a heterocyclic ring containing an sp2 carbon atom and a carbon atom of a carbonyl group or a thiocarbonyl group; each of R₁₁ and R₁₂ independently represents a hydrogen atom or a substituent; and B₁ represents an oxygen atom or a sulfur atom.

n₁ represents an integer of from 0 to 2, preferably 0 or 1, and especially preferably 1.

When n₁ is 2, then each R₁₁ and R₁₂ may be the same as or different from every other R₁₁ and R₁₂.

B₁ is preferably an oxygen atom.

Each of R₁₁ and R₁₂ independently represents a hydrogen atom or a substituent. As for the substituents represented by R₁₁ and R₁₂, the following can be independently exemplified as a substituent W.

Examples of the substituent W include a halogen atom, an alkyl group (inclusive of a cycloalkyl group, a bicycloalkyl group, and a tricycloalkyl group), an alkenyl group (inclusive of a cycloalkenyl group and a bicycloalkenyl group), an alkynyl group, an aryl group, a heterocyclic group, a cyano group, a hydroxyl group, a nitro group, a carboxyl group, an alkoxy group, an aryloxy group, a silyloxy group, a heterocyclic oxy group, an acyloxy group, a carbamoyloxy group, an alkoxycarbonyl group, a carbonyl group, a thiocarbonyl group, an oxycarbonyl group, an aryloxycarbonyl group, an amino group (inclusive of an anilino group), an ammonio group, an acylamino group, an aminocarbonylamino group, an alkoxycarbonylamino group, an aryloxycarbonylamino group, a sulfamoylamino group, an alkyl- or arylsulfonylamino group, a mercapto group, an alkylthio group, an arylthio group, a heterocyclic thio group, a sulfamoyl group, a sulfonyl group, a sulfo group, an alkyl- or arylsulfinyl group, an alkyl- or arylsulfonyl group, an acyl group, an aryloxycarbonyl group, an alkoxycarbonyl group, a carbamoyl group, a sulfonylamino group, an aryl or heterocyclic azo group, an imide group, a phosphoryl group, a phosphino group, a phosphinyl group, a phosphinyloxy group, a phosphinylamino group, a phosphono group, a silyl group, a hydrazino group, a ureido group, a boronic acid group (—B(OH)₂), a phosphato group (—OPO(OH)₂), a sulfato group (—OSO₃H), and other known substituents.

Each of R₁₁ and R₁₂ is independently preferably a hydrogen atom or a substituent having a total carbon atom number of from 1 to 18 (more preferably from 1 to 4); more preferably a hydrogen atom, an alkyl group, an alkenyl group, an aryl group, an alkoxy group, an aryloxy group, a carbonyl group, a thiocarbonyl group, an oxycarbonyl group, an acylamino group, a carbamoyl group, a sulfonylamino group, a sulfamoyl group, a sulfonyl group, a sulfinyl group, a phosphoryl group, a cyano group, an imino group, a halogen atom, a silyl group, or an aromatic heterocyclic group; still more preferably a hydrogen atom or an alkyl group (for example, a methyl group, an ethyl group, a propyl group, and a butyl group); and especially preferably a hydrogen atom.

Each of R₁₁ and R₁₂ may independently further have a substituent. Examples of the further substituent include those exemplified above for the substituent W.

R₁₁ and R₁₂ may be connected to each other to form a ring. Preferred examples of the ring to be formed include a cyclohexene ring, a cyclopentene ring, a benzene ring, and a thiophene ring.

A₁₁ represents a heterocyclic ring, preferably a 6-membered heterocyclic ring, and more preferably a heterocyclic ring containing at least one nitrogen atom. In addition, A₁₁ is a divalent substituent in the structure of the general formula (1). As for this ring structure (Hw), a pyrrole ring, an imidazole ring, an oxazole ring, a thiazole ring, a selenazole ring, a tetrazole ring, a pyridine ring, a pyrazine ring, a pyrimidine ring, a pyridazine ring, an indolizine ring, an indole ring, a quinolidine ring, a quinoline ring, a phthalazine ring, a naphthylidine ring, a quinoxaline ring, a quinoxazoline ring, an isoquinoline ring, a phenanthridine ring, an acridine ring, a phenanthroline ring, a phenazine ring, and aromatic condensed ring structures thereof are preferable. A more preferred ring structure is represented by the following general formula (2).

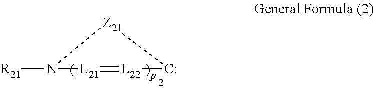

In the general formula (2), Z₂₁ represents an atomic group for forming a nitrogen-containing heterocyclic ring; R₂₁ represents a hydrogen atom or a substituent; each of L₂₁ and L₂₂ represents a methine group; p₂ represents an integer of 0 or 1; and : represents a substitution position in the general formula (1).

Examples of the nitrogen-containing heterocyclic ring formed by Z₂₁ include those exemplified above for Hw. Preferred examples of the nitrogen-containing heterocyclic ring include an oxazole ring having a carbon atom number (hereinafter referring to a total sum of carbon atoms constituting the nitrogen-containing heterocyclic ring and carbon numbers of a substituent substituting on the ring) of from 3 to 25 (for example, 2-3-methyloxazolyl, 2-3-ethyloxazolyl, 2-3-sulfopropyloxazolyl, 2-6-dimethylamino-3-methylbenzoxazolyl, 2-3-ethylbenzoxazolyl, 2-3-sulfopropyl-γ-naphthoxazolyl, 2-3-ethyl-α-naphthoxazolyl, 2-3-methyl-β-naphthoxazolyl, 2-3-sulfopropyl-β-naphthoxazolyl, 2-5-chloro-3-ethyl-α-naphthoxazolyl, 2-5-chloro-3-ethylbenzoxazolyl, 2-5-chloro-3-sulfopropylbenzoxazolyl, 2-5,6-dichloro-3-sulfopropylbenzoxazolyl, 2-5-bromo-3-sulfopropylbenzoxazolyl, 2-3-ethyl-5-phenylbenzoxazolyl, 2-5-phenyl-3-sulfopropylbenzoxazolyl, 2-5-(4-bromophenyl)-3-sulfobutylbenzoxazolyl, 2-5-(1-pyrrolyl)-3-sulfopropylbenzoxazolyl, 2-5,6-dimethyl-3-sulfopropylbenzoxazolyl, 2-3-ethyl-5-methoxybenzoxazolyl, 2-3-ethyl-5-sulfobenzoxazolyl, 2-3-methyl-α-naphthoxazolyl, 2-3-ethyl-β-naphthoxazolyl, and 2-3-methyl-γ-naphthoxazolyl), a thiazole ring having a carbon atom number of from 3 to 25 (for example, 2-3-methylthiazolyl, 2-3-ethylthiazolyl, 2-3-sulfopropylthiazolyl, 2-3-methylbenzothiazolyl, 2-3-sulfopropylbenzothiazolyl, 2-3-methyl-α-naphthothiazolyl, 2-3-methyl-β-naphthothiazolyl, 2-3-ethyl-γ-naphthothiazolyl, 2-3,5-dimethylbenzothiazolyl, 2-5-chloro-3-ethylbenzothiazolyl, 2-5-chloro-3-sulfopropylbenzothiazolyl, 2-3-ethyl-5-iodobenzothiazolyl, 2-5-bromo-3-methylbenzothiazolyl, 2-3-ethyl-5-methoxybenzothiazolyl, and 2-5-phenyl-3-sulfopropylbenzothiazolyl), an imidazole ring having a carbon atom number of from 3 to 25 (for example, 2-1,3-dimethylimidazolyl, 2-1,3-diethylimidazolyl, 2-1,3-dimethylbenzimidazolyl, 2-5,6-dichloro-1,3-dimethylbenzimidazolyl, 2-5,6-dichloro-3-ethyl-1-sulfopropylbenzimidazolyl 2-5-chloro-6-cyano-1,3-diethylbenzimidazolyl, 2-5-chloro-1,3-diethyl-6-trifluoromethylbenzimidazolyl, 2-1,3-dimethyl-β-naphthimidazolyl, and 2-1,3-dimethyl-γ-naphthimidazolyl), an indolenine ring having a carbon atom number of from 10 to 30 (for example, 3,3-dimethyl-1-methylindolenine, 3,3-dimethyl-1-phenylindolenine, 3,3-dimethyl-1-pentylindolenine, 3,3-dimethyl-1-sulfopropylindolenine, 5-chloro-1,3,3-trimethylindolenine, 5-methoxy-1,3,3-trimethylindolenine, 5-carboxy-1,3,3-trimethylindolenine, 5-carbamoyl-1,3,3-trimethylindolenine, 1,3,3-trimethyl-4,5-benzindolenine, and 1,3,3-trimethyl-6,7-benzindolenine), a quinoline ring having a carbon atom number of from 9 to 25 (for example, 2-1-ethylquinolyl, 2-1-sulfobutylquinolyl, 4-1-pentylquinolyl, 4-1-sulfoethylquinolyl, and 4-1-methyl-7-chloroquinolyl), a selenazole ring having a carbon atom number of from 3 to 25 (for example, 2-3-methylbenzoselenazolyl), and a pyridine ring having a carbon atom number of from 5 to 25 (for example, 2-pyridyl and 4-pyridyl). Furthermore, other examples thereof include a thiazoline ring, an oxazoline ring, a selenazoline ring, a tellurazoline ring, a tellurazole ring, a benzotellurazole ring, an imidazoline ring, an imidazo[4,5-quinoxaline] ring, an oxadiazole ring, a thiadiazole ring, a tetrazole ring, a pyrimidine ring, a pyrazine ring, a pyridazine ring, an indolizine ring, an indole ring, a quinolizine ring, a phthalazine ring, a naphthylidine ring, a quinoxaline ring, an quinoxazoline ring, an isoquinoline ring, a phenanthridine ring, an acridine ring, a phenanthroline ring, and a phenazine ring.

Such a nitrogen-containing heterocyclic ring may have a substituent, and preferred examples of the substituent include an alkyl group, an alkenyl group, a cycloalkyl group, an aryl group, a heterocyclic group, an alkynyl group, a halogen atom, an amino group, a cyano group, a nitro group, a hydroxyl group, a mercapto group, a carboxyl group, a sulfo group, a phosphonic acid group, an acyl group, an alkoxy group, an aryloxy group, an alkylthio group, an arylthio group, an alkylsulfonyl group, an arylsulfonyl group, a sulfamoyl group, a carbamoyl group, an acylamino group, an imino group, an acyloxy group, an alkoxycarbonyl group, and carbamoylamino group. Of these, an alkyl group, an aryl group, a heterocyclic group, a halogen atom, a cyano group, a carboxyl group, a sulfo group, an alkoxy group, a sulfamoyl group, a carbamoyl group, and an alkoxycarbonyl group are more preferable.

The heterocyclic ring may be further condensed with another ring. Preferred examples of the ring with which the heterocyclic ring is condensed include a benzene ring, a benzofuran ring, a pyridine ring, a pyrrole ring, an indole ring, and a thiophene ring.

The nitrogen-containing heterocyclic ring is preferably an imidazole ring, an oxazole ring, a thiazole ring, a pyridine ring, a quinoline ring, or a 3,3-di-substituted indolenine ring.

R₂₁ is preferably a hydrogen atom, an alkyl group (preferably an alkyl group having a carbon atom number of from 1 to 20, for example, methyl, ethyl, n-propyl, isopropyl, n-butyl, n-pentyl, benzyl, 3-sulfopropyl, 4-sulfobutyl, 3-methyl-3-sulfopropyl, 2′-sulfobenzyl, carboxymethyl, and 5-carboxypentyl), an alkenyl group (preferably an alkenyl group having a carbon atom number of from 2 to 20, for example, vinyl and allyl), an aryl group (preferably an aryl group having a carbon atom number of from 6 to 20, for example, phenyl, 2-chlorophenyl, 4-methoxyphenyl, 3-methylphenyl, and 1-naphthyl), or a heterocyclic group (preferably a heterocyclic group having a carbon atom number of from 1 to 20, for example, pyridyl, thienyl, furyl, thiazolyl, imidazolyl, pyrazolyl, pyrrolidino, piperidino, and morpholino), more preferably an alkyl group or an aryl group, and still more preferably an alkyl group (preferably an alkyl group having a carbon atom number of from 1 to 6).

Each of L₂₁ and L₂₂ independently represents a methine group which may have a substituent (preferred examples of the substituent are the same as those exemplified above for the substituent W). Preferred examples of the substituent include an alkyl group, a halogen atom, a nitro group, an alkoxy group, an aryl group, a nitro group, a heterocyclic group, an aryloxy group, an acylamino group, a carbamoyl group, a sulfo group, a hydroxyl group, a carboxyl group, an alkylthio group, and a cyano group. The substituent is more preferably an alkyl group.

Each of L₂₁ and L₂₂ is preferably an unsubstituted methine group or a methine group substituted with an alkyl group (preferably having a carbon atom number of from 1 to 6), and more preferably an unsubstituted methine group.

p₂ represents an integer of 0 or 1, and preferably 0.

Preferred examples of the structure of the foregoing general formula (2) include the following H-1 to H-13. In the structural formulae, : represents a substitution position in the general formula (1).

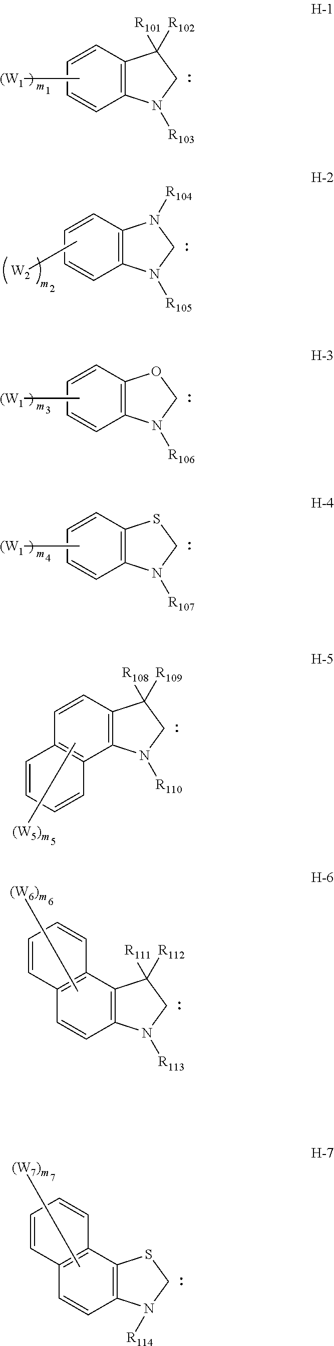

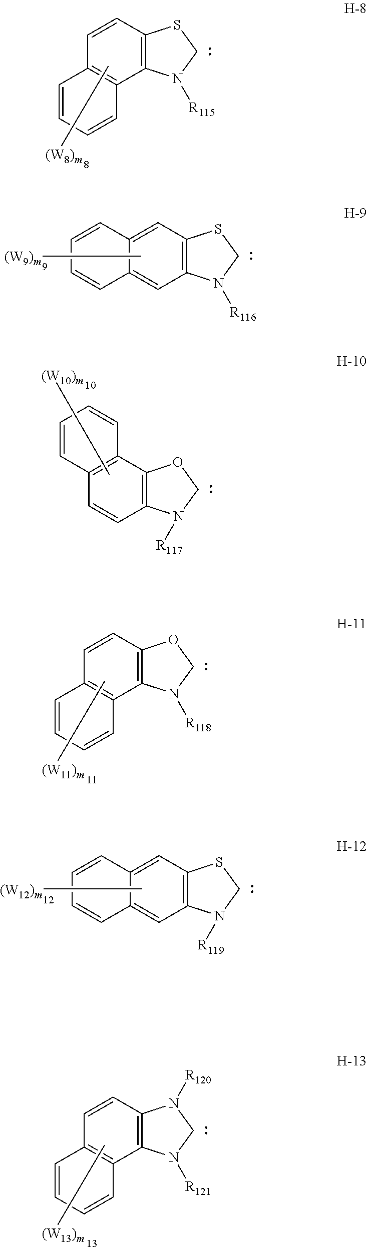

In the foregoing formulae, each of W₁ to W₁₃ represents a hydrogen atom or a substituent; each of R₁₀₁ to R₁₂₁ represents a hydrogen atom or a substituent; each of m₁ to m₄ represents an integer of from 0 to 4; each of m₅ to m₁₃ represents an integer of from 0 to 6; and when each of m₁ to m₁₃ is 2 or more, then each of W₁ to W₁₃ may be the same as or different from every other W₁ to W₁₃.

The substituent represented by each of W₁ to W₁₃ is a monovalent substituent, preferably an alkyl group, an alkenyl group, an aryl group, a halogen atom, an alkoxy group, an alkylamino group, a carbonyl group, a thiocarbonyl group, an oxycarbonyl group, or an aromatic heterocyclic group, and more preferably an alkyl group or an aryl group. A total carbon atom umber thereof is preferably from 1 to 18, and more preferably from 1 to 6. Above all, the substituent represented by each of W₁ to W₁₃ is especially preferably a halogen atom, a methyl group, an ethyl group, a propyl group, or a butyl group. In H-1 to H-13, a number of substituents represented by each of W₁ to W₁₃ is preferably 1 or 2, and more preferably 1.

Each of the substituents represented by R₁₀₁ to R₁₂₁ can be independently selected from those exemplified above for the substituent W and is preferably an alkyl group, an alkenyl group, an aryl group, or an aromatic heterocyclic group, more preferably an alkyl group or an aryl group, and especially preferably an alkyl group. A total carbon atom umber thereof is preferably from 1 to 18, more preferably from 1 to 6, and still more preferably from 1 to 4. Above all, the substituent represented by each of R₁₀₁ to R₁₂₁ is especially preferably a methyl group, an ethyl group, a propyl group, or a butyl group.

A₁₂ represents a heterocyclic ring containing an sp2 carbon atom and a carbon atom of a carbonyl group or a thiocarbonyl group. Though the heterocyclic group represented by A₁₂ may be any heterocyclic group, it is preferably a 5-membered or 6-membered heterocyclic ring, and more preferably a 6-membered heterocyclic ring. In addition, A₁₂ is preferably an acidic nucleus of the merocyanine dye.

The acidic nucleus as referred to herein is, for example, described in James ed., The Theory of the Photographic Process, 4th Edition, Macmillan Publishing Co., 1977, pages 197 to 200. Specifically, examples of the acidic nucleus include those described in U.S. Pat. Nos. 3,567,719, 3,575,869, 3,804,634, 3,837,862, 4,002,480, and 4,925,777, JP-A-3-167549, and U.S. Pat. Nos. 5,994,051 and 5,747,236.

The acidic nucleus is preferably a heterocyclic ring composed of carbon, nitrogen, and/or a chalcogen (typically oxygen, sulfur, selenium, and tellurium) atom (preferably a 5-membered or 6-membered nitrogen-containing heterocyclic ring), and more preferably a 5-membered or 6-membered nitrogen-containing heterocyclic ring composed of carbon, nitrogen, and/or a chalcogen (typically oxygen, sulfur, selenium, and tellurium) atom.

Specifically, examples of the acidic nucleus include the following nuclei.

Examples of the acidic nucleus include nuclei of 2-pyrazolin-5-one, pyrazolidine-3,5-dione, imidazolin-5-one, hydantoin, 2- or 4-thiohydantoin, 2-iminooxazolidin-4-one, 2-oxazolin-5-one, 2-thiooxazolidine-2,5-dione, 2-thiooxazoline-2,4-dione, isooxazolin-5-one, 2-thiazolin-4-one, thiazolidin-4-one, thiazolidine-2,4-dione, rhodanine, thiazolidine-2,4-dione, isorhodanine, indane-1,3-dione, thiophen-3-one, thiophen-3-one-1,1-dioxide, indolin-2-one, indolin-3-one, 2-oxoindazolinium, 3-oxoindazolinium, 5,7-dioxo-6,7-dihydrothiazolo[3,2-a]pyrimidine, cyclohexane-1,3-dione, 3,4-dihydroisoquinolin-4-one, 1,3-dioxane-4,6-dione, barbituric acid, 2-thiobarbituric acid, chroman-2,4-dione, indazolin-2-one, pyrido[1,2-a]pyrimidine-1,3-dione, pyrazolo[1,5-b]quinazolone, pyrazolo[1,5-a]benzimidazole, pyrazolopyridone, 1,2,3,4-tetrahydroquinoline-2,4-dione, 3-oxo-2,3-dihydrobenzo[d]thiophene-1,1-dioxide, and 3-dicyanomethine-2,3-dihydrobenzo[d]thiophene-1,1-dioxide.

Such an acidic nucleus may be condensed with a ring or may be substituted with a substituent (for example, those exemplified above for W).

A₁₂ is more preferably hydantoin, 2- or 4-thiohydantoin, 2-oxazolin-5-one, 2-thiooxazoline-2,4-dione, thiazolidine-2,4-dione, rhodanine, thiazolidine-2,4-dithione, barbituric acid, or 2-thiobarbituric acid, especially preferably hydantoin, 2- or 4-thiohydantoin, 2-oxazolin-5-one, rhodanine, barbituric acid, or 2-thiobarbituric acid, and most preferably 2-thiobarbituric acid.

A₁₂ represents an atomic group capable of constituting a heterocyclic ring containing a thiocarbonyl group, preferably a 5-membered or 6-membered ring, and especially preferably a 6-membered ring. A₁₂ is especially preferably thiobarbituric acid.

The compound represented by the general formula (1) is more preferably a compound represented by the following general formula (3).

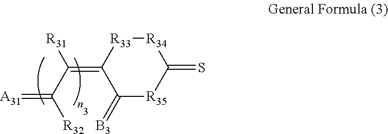

In the general formula (3), A₃₁ represents a heterocyclic ring; each of R₃₁ and R₃₂ independently represents a hydrogen atom or a substituent; n₃ represents an integer of from 0 to 2; each of R₃₃, R₃₄, and R₃₅ independently represents a divalent group capable of constituting a heterocyclic group which will become a 6-membered ring; and B₃ represents an oxygen atom or a sulfur atom.

In the general formula (3), A₃₁, R₃₁, R₃₂, n₃, and B₃ are synonymous with A₁₁, R₁₁, R₁₂, n₁, and B₁ in the general formula (1), respectively, and preferred examples thereof are also the same.

In the general formula (3), each of R₃₃, R₃₄, and R₃₅ independently represents a divalent group capable of constituting a heterocyclic group which will become a 6-membered ring and represents a carbonyl group, a thiocarbonyl group, a methylene group, a methine group, or an imino group (N—R₃₆), and preferably a carbonyl group or an imino group. In the case of an imino group, R₃₆ represents a hydrogen atom, an alkyl group having a carbon atom number of from 1 to 12, an aryl group having a carbon atom number of from 6 to 12, or a heterocyclic group having a carbon atom number of from 2 to 12, and especially preferably a hydrogen atom, an alkyl group having a carbon atom number of from 1 to 6, and an aryl group having a carbon atom number of from 6 to 10. Above all, it is the most preferable that R₃₃ represents a carbonyl group, and that each of R₃₄ and R₃₅ represents an imino group. Incidentally, each of R₃₄ and R₃₅ may be further condensed with a ring structure.

Specific examples of the merocyanine dye are hereunder described, but it should not be construed that the invention is limited thereto.

General Formula (4)

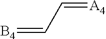

| B₄ | A₄ |
|---|---|
| 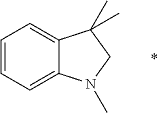 | 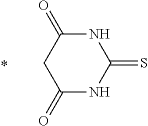 |
| 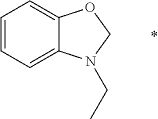 | 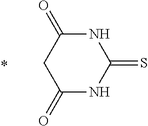 |
| 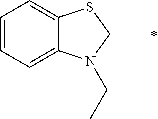 | 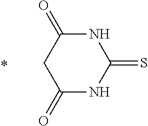 |
| 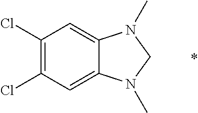 | 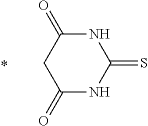 |
| 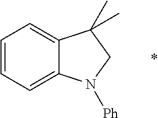 | 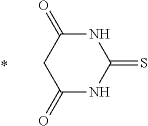 |
| 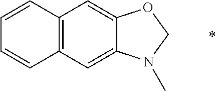 | 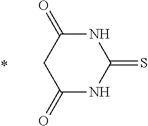 |
| 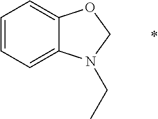 | 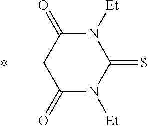 |
| 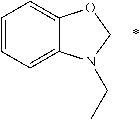 | 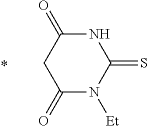 |
| 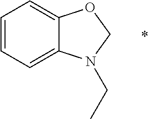 | 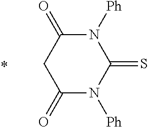 |
| 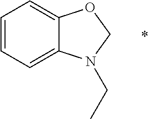 | 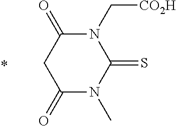 |
| 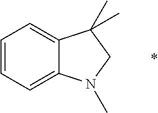 | 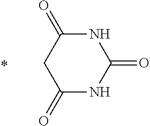 |
| 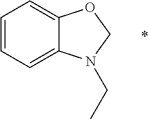 | 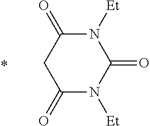 |

In the structural formulae of B₄ and A₄, “*” represents a bonding position to the double bond in the general formula (4).

General Formula (4)

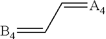

| B₄ | A₄ |
|---|---|
| 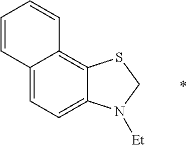 | 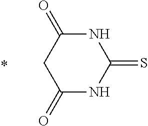 |
| 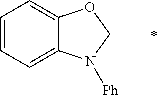 | 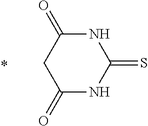 |
| 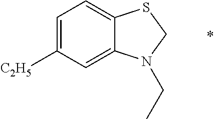 | 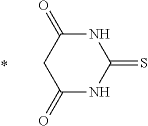 |
| 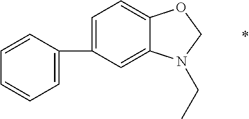 | 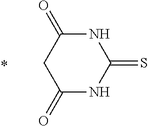 |
| 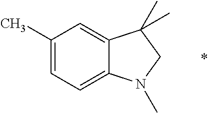 | 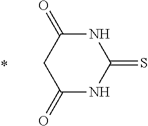 |
| 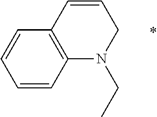 | 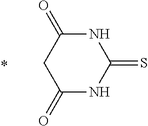 |
| 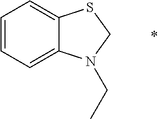 | 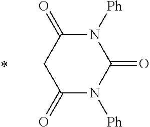 |
| 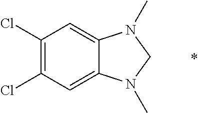 | 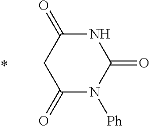 |
| 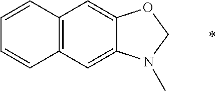 | 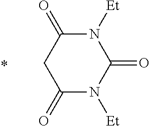 |
| 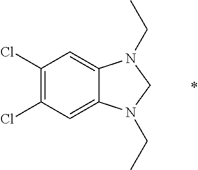 | 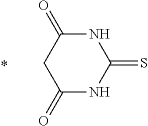 |
| 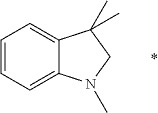 | 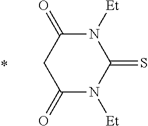 |
| 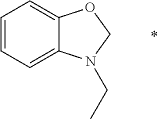 | 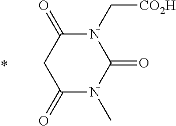 |

In the structural formulae of B₄ and A₄, “*” represents a bonding position to the double bond in the general formula (4).

General Formula (5)
B₅═A₅

| B₅ | A₅ |
|---|---|
| 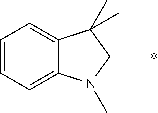 | 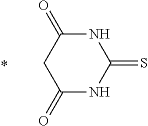 |
| 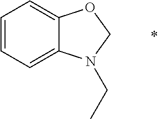 | 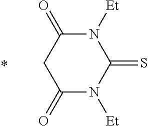 |
| 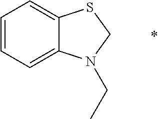 | 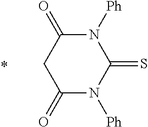 |
| 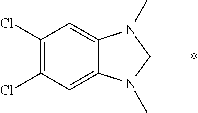 | 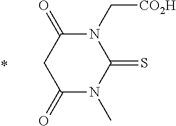 |
| 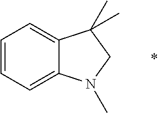 | 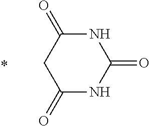 |
| 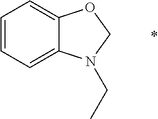 | 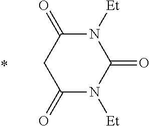 |
| 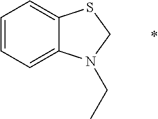 | 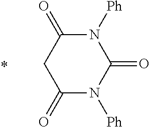 |

In the structural formulae of B₅ and A₅, “*” represents a bonding position to the double bond in the general formula (5).

The compound according to the invention is a known compound such as usual merocyanine dyes, and these dye compounds can be synthesized by reference to dye documents regarding methine dyes as described later, and the like.

An absorption maximum wavelength of the merocyanine dye represented by the general formula (1) in a solution state (chloroform solution) in a visible region preferably falls within the range of from 400 to 500 nm. The use of the merocyanine dye having an absorption maximum wavelength falling within the foregoing range is preferable because the photoselection against B light increases, and the color mixing ratio of G light against B light is lowered, so that an imaging device with high color reproducibility can be constituted.

### [Orientation Control of Photoelectric Conversion Layer]

As for the organic compound which is used for the photoelectric conversion layer, a compound having a π-conjugated electron is preferably used. It is preferable that this n-electron plane is not vertical to a substrate (electrode substrate) and is oriented at an angle close to parallel to the substrate as far as possible. The angle against the substrate is preferably 0° or more and not more than 80°, more preferably 0° or more and not more than 60°, still more preferably 0° or more and not more than 40°, yet still more preferably 0° or more and not more than 20°, especially preferably 0° or more and not more than 10°, and most preferably 0° (namely, in parallel to the substrate). A dye satisfying such a requirement is the foregoing merocyanine dye.

In the invention, a color photoelectric conversion device in which BGR photoelectric conversion layers with good color reproducibility, namely three layers inclusive of a blue photoelectric conversion layer, a green photoelectric conversion layer, and a red photoelectric conversion layer, are stacked can be preferably used. As for the photoelectric conversion layer according to the invention, all of BGR photoelectric conversion layers can be fabricated by selecting a material to be used. However, it is preferable to use the compound represented by the foregoing general formula (1) for a blue photoelectric conversion layer.

The compound represented by the general formula (1) is preferably used as an organic p-type semiconductor.

### [Photoelectric Conversion Layer]

The photoelectric conversion layer preferably contains an organic p-type semiconductor (compound) and an organic n-type semiconductor (compound), and these may be any compound. In addition, though such a compound may or may not have absorption in visible and infrared regions, the case of using at least one compound (organic dye) having absorption in a visible region is preferable. Furthermore, colorless p-type compound and n-type compound may be used, and an organic dye may be added thereto.

The organic p-type semiconductor (compound) is an organic semiconductor (compound) having donor properties and refers to an organic compound which is mainly represented by a hole transporting organic compound and which has such properties that it is liable to provide an electron. In more detail, the organic p-type semiconductor (compound) refers to an organic compound having a smaller ionization potential in two organic materials when they are brought into contact with each other and used. Accordingly, as for the organic compound having donor properties, any organic compound may be used so far as it is an electron donating organic compound. Useful examples thereof include triarylamine compounds, benzidine compounds, pyrazoline compounds, styrylamine compounds, hydrazone compounds, triphenylmethane compounds, carbazole compounds, polysilane compounds, thiophene compounds, phthalocyanine compounds, cyanine compounds, merocyanine compounds, oxonol compounds, polyamine compounds, indole compounds, pyrrole compounds, pyrazole compounds, polyarylene compounds, condensed aromatic carbocyclic compounds (for example, naphthalene derivatives, anthracene derivatives, phenanthrene derivatives, tetracene derivatives, pyrene derivatives, perylene derivatives, and fluoranthene derivatives), and metal complexes having, as a ligand, a nitrogen-containing heterocyclic compound. Incidentally, the invention is not limited to these compounds, and as described above, an organic compound having a smaller ionization potential than that of an organic compound to be used as an n-type compound (having acceptor properties) may be used as the organic semiconductor having donor properties.

The organic n-type semiconductor (compound) is an organic semiconductor (compound) having acceptor properties and refers to an organic compound which is mainly represented by an electron transporting organic compound and which has such properties that it is liable to accept an electron. In more detail, the organic n-type semiconductor (compound) refers to an organic compound having a larger electron affinity in two organic compounds when they are brought into contact with each other and used. Accordingly, as for the organic compound having acceptor properties, any organic compound can be used so far as it is an electron accepting organic compound. Useful examples thereof include condensed aromatic carbocyclic compounds (for example, naphthalene derivatives, anthracene derivatives, phenanthrene derivatives, tetracene derivatives, pyrene derivatives, perylene derivatives, and fluoranthene derivatives), 5-membered to 7-membered heterocyclic compounds containing a nitrogen atom, an oxygen atom, or a sulfur atom (for example, pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, benzothiazole, carbazole, purine, triazolopyridazine, triazolopyrimidine, tetrazaindene, oxadiazole, imidazopyridine, pyralidine, pyrrolopyridine, and thiadiazolopyridine), polyarylene compounds, fluorene compounds, cyclopentadiene compounds, silyl compounds, and metal complexes having, as a ligand, a nitrogen-containing heterocyclic compound. Incidentally, the invention is not limited to these compounds, and as described above, an organic compound having a larger electron affinity than that of an organic compound to be used as an organic compound having donor properties may be used as the organic semiconductor having acceptor properties.

Though any organic dye may be used as the organic dye to be used for the photoelectric conversion layer, the case of using a p-type organic dye or an n-type organic dye is preferable. Though any organic dye may be used as the organic dye, preferred examples thereof include cyanine dyes, styryl dyes, hemicyanine dyes, merocyanine dyes (inclusive of zeromethinemerocyanine (simple merocyanine)), trinuclear merocyanine dyes, tetranuclear merocyanine dyes, rhodacyanine dyes, complex cyanine dyes, complex merocyanine dyes, alopolar dyes, oxonol dyes, hemioxonol dyes, squarylium dyes, croconium dyes, azamethine dyes, coumarin dyes, arylidene dyes, anthraquinone dyes, triphenylmethane dyes, azo dyes, azomethine dyes, Spiro compounds, metallocene dyes, fluorenone dyes, flugide dyes, perylene dyes, perinone dyes, phenazine dyes, phenothiazine dyes, quinone dyes, diphenylmethane dyes, polyene dyes, acridine dyes, acridinone dyes, diphenylamine dyes, quinacridone dyes, quinophthalone dyes, phenoxazine dyes, phthaloperylene dyes, diketopyrrolopyrole dyes, dioxane dyes, porphyrin dyes, chlorophyll dyes, phthalocyanine dyes, metal complex dyes, and condensed aromatic carbocyclic dyes (for example, naphthalene derivatives, anthracene derivatives, phenanthrene derivatives, tetracene derivatives, pyrene derivatives, perylene derivatives, and fluoranthene derivatives).

As for the color imaging device that is one of the objects of the invention, there may be the case where a methine dye having a high degree of freedom for the adjustment of absorption wavelength, such as cyanine dyes, styryl dyes, hemicyanine dyes, merocyanine dyes, trinuclear merocyanine dyes, tetranuclear merocyanine dyes, rhodacyanine dyes, complex cyanine dyes, complex merocyanine dyes, alopolar dyes, oxonol dyes, hemioxonol dyes, squarylium dyes, croconium dyes, and azamethine dyes, gives adaptability to the wavelength.

Details of these methine dyes are described in the following dye documents.

### [Dye Documents]

F. M. Harmer, Heterocyclic Compounds—Cyanine Dyes and Related Compounds, John Wiley & Sons, New York and London, 1964; D. M. Stunner, Heterocyclic Compounds—Special topics in heterocyclic chemistry, Chapter 18, Paragraph 14, pages 482 to 515, John Wiley & Sons, New York and London, 1977; Rodd Chemistry of Carbon Compounds, 2nd Ed., Vol. IV, Part B, 1977, Chapter 15, pages 369 to 422, Elsevier Science Publishing Company Inc., New York; and the like.

When the explanation is further added, dyes described in Research Disclosure (RD) 17643, pages 23 to 24; RD 18716, page 648, right-hand column to page 649, right-hand column; RD 308119, page 996, right-hand column to page 998, right-hand column; and European Patent No. 0565096A1, page 65, lines 7 to 10 can be preferably used. In addition, dyes having a partial structure or a structure represented by a general formula or a specific example, as described in U.S. Pat. No. 5,747,236 (in particular, pages 30 to 39), U.S. Pat. No. 5,994,051 (in particular, pages 32 to 43), and U.S. Pat. No. 5,340,694 (in particular, pages 21 to 58, with proviso that in the dyes represented by (XI), (XII) and (XIII), the number of each of n₁₂, n₁₅, n₁₇ and n₁₈ is not limited and is an integer of 0 or more (preferably not more than 4)) can be preferably used, too.

Next, a metal complex compound which can be used for the photoelectric conversion layer and other organic layer is described. The metal complex compound is a metal complex having a ligand containing at least one of a nitrogen atom, an oxygen atom, and a sulfur atom as coordinated to a metal. Though a metal ion in the metal complex is not particularly limited, it is preferably a beryllium ion, a magnesium ion, an aluminum ion, a gallium ion, a zinc ion, an indium ion, or a tin ion; more preferably a beryllium ion, an aluminum ion, a gallium ion, or a zinc ion; and still more preferably an aluminum ion or a zinc ion. As the ligand which is contained in the metal complex, there are enumerated various known ligands. Examples thereof include ligands described in H. Yersin, Photochemistry and Photophysics of Coordination Compounds, Springer-Verlag, 1987; and Akio Yamamoto, Organometallic Chemistry—Principles and Applications, Shokabo Publishing Co., Ltd., 1982.

The foregoing ligand is preferably a nitrogen-containing heterocyclic ligand (having preferably a carbon atom number of from 1 to 30, more preferably a carbon atom number of from 2 to 20, and especially preferably a carbon atom number of from 3 to 15, which may be a monodentate ligand or a bidentate or polydentate ligand, with a bidentate ligand being preferable; and examples of which include a pyridine ligand, a bipyridyl ligand, a quinolinol ligand, and a hydroxyphenylazole ligand (for example, a hydroxyphenylbenzimidazole ligand, a hydroxyphenylbenzoxazole ligand, and a hydroxyphenylimidazole ligand), an alkoxy ligand (having preferably a carbon atom number of from 1 to 30, more preferably a carbon atom number of from 1 to 20, and especially preferably a carbon atom number of from 1 to 10, examples of which include methoxy, ethoxy, butoxy, and 2-ethylhexyloxy), an aryloxy ligand (having preferably a carbon atom number of from 6 to 30, more preferably a carbon atom number of from 6 to 20, and especially preferably a carbon atom number of from 6 to 12, examples of which include phenyloxy, 1-naphthyloxy, 2-naphthyloxy, 2,4,6-trimethylphenyloxy, and 4-biphenyloxy), an aromatic heterocyclic oxy ligand (having preferably a carbon atom number of from 1 to 30, more preferably a carbon atom number of from 1 to 20, and especially preferably a carbon atom number of from 1 to 12, examples of which include pyridyloxy, pyrazyloxy, pyrimidyloxy, and quinolyloxy), an alkylthio ligand (having preferably a carbon atom number of from 1 to 30, more preferably a carbon atom number of from 1 to 20, and especially preferably a carbon atom number of from 1 to 12, examples of which include methylthio and ethylthio), an arylthio ligand (having preferably a carbon atom number of from 6 to 30, more preferably a carbon atom number of from 6 to 20, and especially preferably a carbon atom number of from 6 to 12, examples of which include phenylthio), a heterocyclic ring-substituted thio ligand (having preferably a carbon atom number of from 1 to 30, more preferably a carbon atom number of from 1 to 20, and especially preferably a carbon atom number of from 1 to 12, examples of which include pyridylthio, 2-benzimidazolylthio, 2-benzoxazolylthio, and 2-benzothiazolylthio), or a siloxy ligand (having preferably a carbon atom number of from 1 to 30, more preferably a carbon atom number of from 3 to 25, and especially preferably a carbon atom number of from 6 to 20, examples of which include a triphenylsiloxy group, a triethoxysiloxy group, and a triisopropylsiloxy group); more preferably a nitrogen-containing heterocyclic ligand, an aryloxy ligand, an aromatic heterocyclic oxy ligand, or a siloxy ligand; and still more preferably a nitrogen-containing heterocyclic ligand, an aryloxy ligand, or a siloxy ligand.

In the photoelectric conversion layer having a layer of a p-type semiconductor and a layer of an n-type semiconductor (preferably a mixed or dispersed (bulk heterojunction structure) layer) between a pair of electrodes, the case of a photoelectric conversion layer which is characterized by containing an orientation-controlled organic compound in at least one of the p-type semiconductor and the n-type semiconductor is preferable.

### (Formation Method of Organic Layer)

A layer containing such an organic compound is deposited by a dry deposition method or a wet deposition method. Specific examples of the dry deposition method include physical vapor deposition methods such as a vacuum vapor deposition method, a sputtering method, an ion plating method, and an MBE method, and CVD methods such as plasma polymerization. Examples of the wet deposition method include a casting method, a spin coating method, a dipping method, and an LB method.

In the case of using a polymer compound as at least one of the p-type semiconductor (compound) and the n-type semiconductor (compound), it is preferable that the deposition is achieved by a wet deposition method which is easy for the fabrication. In the case of adopting a dry deposition method such as vapor deposition, the use of a polymer compound is difficult because of possible occurrence of decomposition. Accordingly, its oligomer can be preferably used as a replacement.

On the other hand, in the invention, in the case of using a low molecular weight compound, a dry deposition method is preferably adopted, and a vacuum vapor deposition method is especially preferably adopted. In the vacuum vapor deposition method, a method for heating a compound such as a resistance heating vapor deposition method and an electron beam heating vapor deposition method, the shape of a vapor deposition source such as a crucible and a boat, a degree of vacuum, a vapor deposition temperature, a substrate temperature, a vapor deposition rate, and the like are a basic parameter. In order to make it possible to achieve uniform vapor deposition, it is preferable that the vapor deposition is carried out while rotating the substrate. A high degree of vacuum is preferable. The vacuum vapor deposition is carried out at a degree of vacuum of not more than 10⁻⁴ Ton, preferably not more than 10⁻⁶ Torr, and especially preferably not more than 10⁻⁸ Torr. It is preferable that all steps at the time of vapor deposition are carried out in vacuo. Basically, the vacuum vapor position is carried out in such a manner that the compound does not come into direct contact with the external oxygen and moisture. The foregoing condition of the vacuum vapor deposition is required to be strictly controlled because it affects crystallinity, amorphous properties, density, compactness, and the like of the organic layer. It is preferably employed to subject the vapor deposition rate to PI or PID control using a layer thickness monitor such as a quartz oscillator and an interferometer. In the case of vapor depositing two or more kinds of compounds at the same time, a co-vapor deposition method, a flash vapor deposition method, and the like can be preferably adopted.

### [Regulation of Layer Thickness of Photoelectric Conversion Layer]

In the case of using the photoelectric conversion layer according to the invention as a color imaging device (image sensor), for the purposes of enhancing the photoelectric conversion efficiency and further improving color separation without passing excessive light through a lower layer, a light absorptance of the photoelectric conversion layer of each of B, G and R layers is preferably regulated to 50% or more, more preferably 70% or more, especially preferably 90% (absorbance=1) or more, and most preferably 99% or more. Accordingly, from the standpoint of light absorption, it is preferable that the layer thickness of the photoelectric conversion layer is thick as far as possible. However, taking into consideration a proportion for contributing to the charge separation, the layer thickness of the photoelectric conversion layer in the invention is preferably 30 nm or more and not more than 400 nm, more preferably 50 nm or more and not more than 300 nm, especially preferably 80 nm or more and not more than 250 nm, and most preferably 100 nm or more and not more than 200 nm.

### [Impression of Voltage]

The case of impressing voltage to the photoelectric conversion layer according to the invention is preferable in view of enhancing the photoelectric conversion efficiency. Though any voltage may be useful as the voltage to be impressed, necessary voltage varies with the layer thickness of the photoelectric conversion layer. That is, the larger an electric field to be added in the photoelectric conversion layer, the more enhanced the photoelectric conversion efficiency is. However, even when the same voltage is impressed, the thinner the layer thickness of the photoelectric conversion layer, the larger the electric field to be added is. Accordingly, in the case where the layer thickness of the photoelectric conversion film is thin, the voltage to be impressed may be relatively small. The electric field to be impressed to the photoelectric conversion layer is preferably 1×10⁻² V/cm or more, more preferably 1×10 V/cm or more, still more preferably 1×10³ V/cm or more, especially preferably 1×10⁴ V/cm or more, and most preferably 1×10⁵ V/cm or more. Though there is no particular upper limit, when the electric field is excessively added, an electric current flows even in a dark place, and therefore, such is not preferable. The electric field is preferably not more than 1×10¹⁰ V/cm, and more preferably not more than 1×10⁷ V/cm.

### [General Requirements]

In the invention, the photoelectric conversion device has preferably a configuration in which at least two layers are stacked, more preferably a configuration in which three layers or four layers are stacked, and especially preferably a configuration in which three layers are stacked. In these cases, at least one layer is a photoelectric conversion layer containing a merocyanine dye.

In the invention, such a photoelectric conversion device can be preferably used as an imaging device, and especially preferably as a solid-sate imaging device. In addition, in the invention, the case where voltage is impressed to the photoelectric conversion layer, the photoelectric conversion device, or the imaging device is preferable.

The case where the photoelectric conversion device in the invention has a photoelectric conversion layer having a stacked structure in which a layer of the p-type semiconductor and a layer of the n-type semiconductor are disposed between a pair of electrodes is preferable. In addition, the case where at least one of the p-type semiconductor and the n-type semiconductor contains an organic compound is preferable; and the case where both the p-type semiconductor and the n-type semiconductor contain an organic compound is more preferable.

### [Bulk Heterojunction Structure]

In the invention, the case containing a photoelectric conversion layer (photosensitive layer) having a p-type semiconductor layer and an n-type semiconductor layer between a pair of electrodes, with at least one of the p-type semiconductor layer and the n-type semiconductor layer being an organic semiconductor, and a bulk heterojunction structure layer containing the p-type semiconductor and the n-type semiconductor as an interlayer between these semiconductor layers is preferable. In such case, in the photoelectric conversion layer, by allowing a bulk heterojunction structure to contain in the organic layer, a drawback that the organic layer has a short carrier diffusion length is compensated, thereby enhancing the photoelectric conversion efficiency.

Incidentally, the bulk heterojunction structure is described in detail in JP-A-2005-303266.

### [Tandem Structure]

In the invention, the case containing a photoelectric conversion layer (photosensitive layer) having a structure having the number of a repeating structure (tandem structure) of a pn junction layer formed of the p-type semiconductor layer and the n-type semiconductor layer between a pair of electrodes of 2 or more is preferable. In addition, a thin layer made of an electrically conductive material may be inserted between the foregoing repeating structures. The electrically conductive material is preferably silver or gold, and most preferably silver. The number of the repeating structure (tandem structure) of a pn junction layer may be any number. For the purpose of increasing the photoelectric conversion efficiency, the number of the repeating structure (tandem structure) of a pn junction layer is preferably 2 or more and not more than 100, more preferably 2 or more and not more than 50, especially preferably 5 or more and not more than 40, and most preferably 10 or more and not more than 30.

In the invention, though the semiconductor having a tandem structure may be made of an inorganic material, it is preferably an organic semiconductor, and more preferably an organic dye.

Incidentally, the tandem structure is described in detail in JP-A-2005-303266.

### [Stacked Structure]

As one of preferred embodiments of the invention, in the case where voltage is not impressed to the photoelectric conversion layer, it is preferable that at least two photoelectric conversion layers are stacked. The stacked imaging device is not particularly limited, and all stacked imaging devices which are used in this field are applicable. However, a BGR three-layer stacked structure is preferable.

Next, for example, the solid-state imaging device according to the invention has a photoelectric conversion layer shown in the present embodiment. Then, the solid-state imaging device is provided with a stack type photoelectric conversion layer on a scanning circuit part. For the scanning circuit part, a configuration in which an MOS transistor is formed on a semiconductor substrate for every pixel unit or a configuration having CCD as an imaging device can be properly adopted.

For example, in the case of a solid-state imaging device using an MOS transistor, a charge is generated in a photoelectric conversion layer by incident light which has transmitted through electrodes; the charge runs to the electrodes within the photoelectric conversion layer by an electric field generated between the electrodes by impressing voltage to the electrodes; and the charge is further transferred to a charge accumulating part of the MOS transistor and accumulated in the charge accumulating part. The charge accumulated in the charge accumulating part is transferred to a charge read-out part by switching of the MOS transistor and further outputted as an electric signal. In this way, full-color image signals are inputted in a solid-state imaging apparatus including a signal processing part.

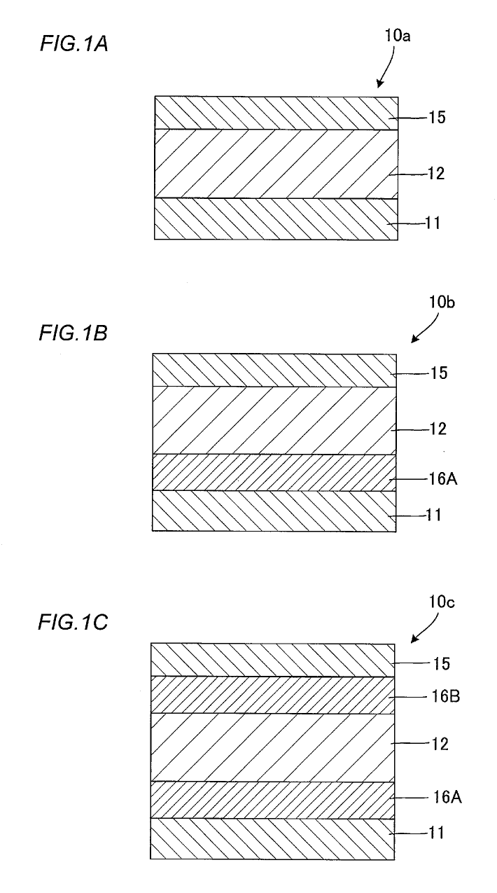

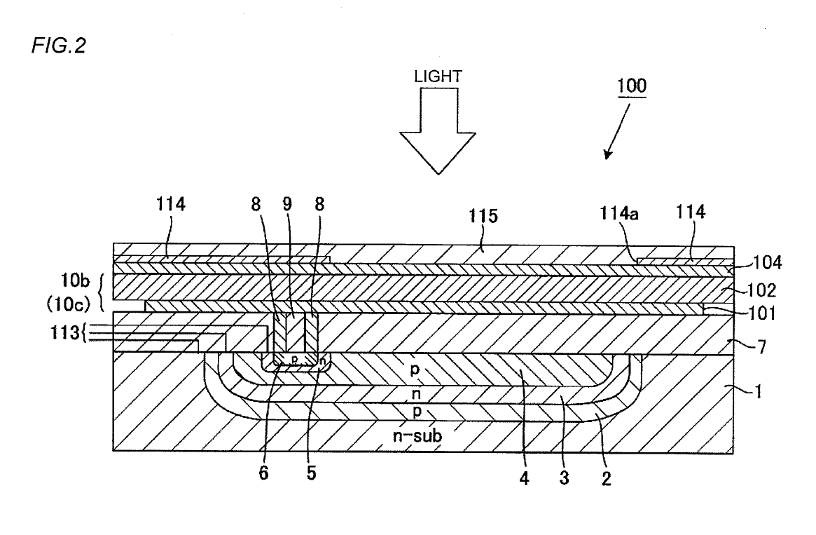

As for such a stacked imaging device, solid color imaging devices represented by those described in FIG. 2 of JP-A-58-103165 and in FIG. 2 of JP-A-58-103166 and the like can also be applied.

As for the manufacturing step of the foregoing stack type imaging device, preferably a three-layer stack type imaging device, a method described in JP-A-2002-83946 (see FIGS. 7 to 23 and paragraphs [0026] to [0038] of this patent document) can be applied.

### (Photoelectric Conversion Device)

The photoelectric conversion device of a preferred embodiment of the invention is hereunder described.

The photoelectric conversion device according to the invention is preferably comprised of an electromagnetic wave absorption/photoelectric conversion site and a charge accumulation of charge generated by photoelectric conversion/transfer/read-out site.

In the invention, the electromagnetic wave absorption/photoelectric conversion site has a stack type structure made of at least two layers, which is capable of at least absorbing each of blue light, green light, and red light and undergoing photoelectric conversion. A blue light photoelectric conversion layer (absorbing layer) (B) is able to absorb at least light of 400 nm or more and not more than 500 nm and preferably has an absorptance of a peak wavelength in that wavelength region of 50% or more. A green light photoelectric conversion layer (absorbing layer) (G) is able to absorb at least light of 500 nm or more and not more than 600 nm and preferably has an absorptance of a peak wavelength in that wavelength region of 50% or more. A red light photoelectric conversion layer (absorbing layer) (R) is able to absorb at least light of 600 nm or more and not more than 700 nm and preferably has an absorptance of a peak wavelength in that wavelength region of 50% or more. The order of these layers is not limited. In the case of a three-layer stack type structure, orders of BGR, BRG, GBR, GRB, RBG and RGB from the upper layer (light incident side) are possible. It is preferable that the uppermost layer is G. In the case of a two-layer stack type structure, when the upper layer is an R layer, BG layers are formed as the lower layer in the same planar state; when the upper layer is a B layer, GR layers are formed as the lower layer in the same planar state; and when the upper layer is a G layer, BR layers are formed as the lower layer in the same planar state. Preferably, the upper layer is formed of a G layer, and the lower layer is formed of BR layers in the same planar state. In the case where two light absorbing layers are provided in the same planar state of the lower layer in this way, it is preferable that a filter layer capable of undergoing color separation is provided in, for example, a mosaic state on the upper layer or between the upper layer and the lower layer. Under some circumstances, it is possible to provide a fourth or polynomial layer as a new layer or in the same planar state.

In the invention, the charge accumulation/transfer/read-out site is provided under the electromagnetic wave absorption/photoelectric conversion site. It is preferable that the electromagnetic wave absorption/photoelectric conversion site which is the lower layer also serves as the charge accumulation/transfer/read-out site.

In the invention, the electromagnetic wave absorption/photoelectric conversion site is made of an organic layer or an inorganic layer or a mixture of an organic layer and an inorganic layer. The organic layer may form B/G/R layers, or the inorganic layer may form B/G/R layers. Preferably, the electromagnetic wave absorption/photoelectric conversion site is made of a mixture of an organic layer and an inorganic layer. In that case, basically, when the organic layer is made of a single layer, the inorganic layer is made of a single layer or two layers; and when the organic layer is made of two layers, the inorganic layer is made of a single layer. In the case where each of the organic layer and the inorganic layer is made of a single layer, the inorganic layer forms electromagnetic wave absorption/photoelectric conversion sites of two or more colors in the same planar state. Preferably, the upper layer is made of an organic layer and constituted of a G layer, and the lower layer is made of an inorganic layer and constituted of a B layer and an R layer in this order from the upper side. Under some circumstances, it is possible to provide a fourth or polynomial layer as a new layer or in the same planar state. When the organic layer forms B/G/R layers, a charge accumulation/transfer/read-out site is provided thereunder. In the case of using an inorganic layer as the electromagnetic wave absorption/photoelectric conversion site, this inorganic layer also serves as the charge accumulation/transfer/read-out site.

In the invention, the following is an especially preferred embodiment among the devices described above.

That is, the preferred embodiment is the case having at least two electromagnetic wave absorption/photoelectric conversion sites, with at least one site thereof being the photoelectric conversion device (imaging device) according to the invention.

Furthermore, the case of a device in which at least two electromagnetic wave absorption/photoelectric conversion sites have a stack type structure of at least two layers is preferable. Furthermore, the case where the upper layer is made of a site capable of absorbing green light and undergoing photoelectric conversion is preferable.

In addition, the case having at least three electromagnetic wave absorption/photoelectric conversion sites, with at least one site thereof being the photoelectric conversion device (imaging device) according to the invention, is especially preferable.

Furthermore, the case of a device in which the upper layer is made of a site capable of absorbing green light and undergoing photoelectric conversion is preferable. Furthermore, the case where at least two electromagnetic wave absorption/photoelectric conversion sites of the three sites are made of an inorganic layer (which is preferably formed within a silicon substrate) is preferable.

### (Hole Blocking Layer)

Since the hole blocking layer is required to make light incident into the photoelectric conversion layer, it is constituted of a material which is transparent against light of from a visible region to an infrared region. In addition, at the time of impressing bias voltage between a first electrode (lower electrode) and a second electrode (upper electrode), the hole blocking layer has a function to suppress the injection of a hole from the upper electrode to the photoelectric conversion layer. Furthermore, the hole blocking layer is required to bring about a function to transport an electron generated in the photoelectric conversion layer into the upper electrode. Incidentally, in the case where the lower electrode is an electrode for collecting an electron, the hole blocking layer may be provided between the photoelectric conversion layer and the lower electrode.

In the case of directly fabricating an upper electrode without depositing a hole blocking layer on the photoelectric conversion layer, there may be the case where the photoelectric conversion layer is damaged at the time of depositing an upper electrode, an organic material constituting the photoelectric conversion layer and a material of the upper electrode cause an interaction, or a localized level is newly formed at the interface between the photoelectric conversion layer and the upper electrode. The hole blocking layer prevents occurrence of an increase of dark current to be caused by the promotion of hole injection from the upper electrode via this localized level, and it is preferable that the hole blocking layer is constituted of a stable inorganic material which hardly causes an interaction with either one or both of the material of the photoelectric conversion layer and the material of the upper electrode. In addition, since the number of localized levels is in proportion to an area of the interface with the upper electrode, for the purpose of making this electrode interface smooth as far as possible, it is preferable that the hole blocking layer is amorphous. Furthermore, in order that after the formation of the photoelectric conversion layer, the incorporation of water, oxygen, and the like which deteriorate the photoelectric conversion layer may be prevented from occurring, the hole blocking layer is preferably made of a material capable of being deposited by a physical vapor deposition method from which it can be fabricated consistently together with the photoelectric conversion layer and the upper electrode under a vacuum condition, such as a vacuum vapor deposition method, a sputtering method, an ion plating method, and a molecular beam epitaxy method.

The hole blocking layer preferably contains an inorganic material.

Examples of the inorganic material which satisfies the foregoing requirements include oxides. Specific examples thereof include aluminum oxide, silicon oxide, titanium oxide, vanadium oxide, manganese oxide, iron oxide, cobalt oxide, zinc oxide, niobium oxide, molybdenum oxide, cadmium oxide, indium oxide, tin oxide, barium oxide, tantalum oxide, tungsten oxide, and iridium oxide. Such an oxide is more preferably an oxide which is shorter in oxygen than a fixed ratio composition (stoichiometric composition) because the electron transporting properties are increased. By forming the hole blocking layer constituted of such an inorganic material between the photoelectric conversion layer and the upper electrode for collecting an electron, it is possible to realize an organic photoelectric conversion device which suppresses the hole injection from the upper electrode to reduce a dark current and from which a high SN ratio is obtained, without reducing the external quantum efficiency.

A thickness of the hole blocking layer is preferably 5 nm or more and not more than 200 nm, more preferably 10 nm or more and not more than 150 nm, and especially preferably 20 nm or more and not more than 100 nm.

### (Electron Blocking Layer)

For the electron blocking layer, an electron donating organic material can be used, and it preferably contains an organic electron blocking material. Specifically, examples of a low molecular weight material which can be used include aromatic diamine compounds such as N,N′-bis(3-methylphenyl)-(1,1′-biphenyl)-4,4′-diamine (TPD) and 4,4′-bis[N-(naphthyl)-N-phenyl-amino]biphenyl (α-NPD), oxazole, oxadiazole, triazole, imidazole, imidazolone, stilbene derivatives, pyrazoline derivatives, tetrahydroimidazole, polyarylalkanes, butadiene, 4,4′,4″-tris(N-(3-methylphenyl)-N-phenylamino)triphenylamine (m-MTDATA), porphyrin compounds such as porphine, tetraphenylporphine copper, phthalocyanine, copper phthalocyanine, and titanium phthalocyanine oxide, triazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, oxazole derivatives, styrylanthracene derivatives, fluorenone derivatives, hydrazone derivatives, and silazane derivatives. Examples of a polymer material which can be used include polymers of, for example, phenylenevinylene, fluorene, carbazole, indole, pyrene, pyrrole, picoline, thiophene, acetylene, diacetylene, or the like, and derivatives of these polymers. It is also possible to use even a compound which is not an electron donating compound but has sufficient hole transporting properties.

A thickness of the electron blocking layer is preferably 10 nm or more and not more than 300 nm, more preferably 30 nm or more and not more than 200 nm, and especially preferably 50 nm or more and not more than 150 nm. This is because when this thickness is too thin, the effect for suppressing a dark current is lowered, whereas when it is too thick, the photoelectric conversion efficiency is lowered. In addition, specific examples of a compound which is preferable as the electron blocking material include Compounds (1) to (16) described in JP-A-2007-59517, paragraphs [0036] to [0037], TPD, and m-MTDATA.

### (Electrode)

The photoelectric conversion device of the invention includes a first electrode, an electron blocking layer, a photoelectric conversion layer containing a merocyanine dye, a hole blocking layer, and a transparent electrode that is a second electrode in this order. The first electrode and the second electrode form a counter electrode to each other. Preferably, a lower layer is a pixel electrode.

It is preferable that the first electrode collects a hole from the hole transporting photoelectric conversion layer or the hole transporting layer, and it is made of a material for which a metal, an alloy, a metal oxide, an electrically conductive compound, or a mixture thereof can be used. In addition, the first electrode is preferably a transparent electrode. It is preferable that the transparent electrode that is the second electrode collects an electron from the electron transporting photoelectric conversion layer or the electron transporting layer and is selected taking into consideration adhesiveness to or electron affinity with an adjacent layer such as the electron transporting photoelectric conversion layer and the electron transporting layer, ionization potential, stability, and the like. Specific examples thereof include tin oxides doped with antimony, fluorine, or the like (for example, ATO and FTO), electrically conductive metal oxides such as tin oxide, zinc oxide, indium oxide, and indium tin oxide (ITO), metals such as gold, silver, chromium, and nickel, mixtures or stacks of such a metal and such an electrically conductive oxide, inorganic electrically conductive substances such as copper iodide and copper sulfide, organic electrically conductive materials such as polyaniline, polythiophene, and polypyrrole, and stacks of a silicon compound and the foregoing material with ITO. Of these, electrically conductive metal oxides are preferable, and ITO and IZO are especially preferable from the standpoints of productivity, high electric conductivity, transparency, and the like. Though the layer thickness can be properly selected depending upon the material, in general, when the electrically conductive layer is made thinner than a certain range, an abrupt increase of resistivity value is brought. Thus, in general, the layer thickness is preferably a range of 1 nm or more and not more than 1 μm, more preferably a range of 3 nm or more and not more than 300 nm, and still more preferably a range of 5 nm or more and not more than 100 nm. A sheet resistance of the electrode is preferably from 100 to 10,000Ω/□.

For the fabrication of the pixel electrode and the counter electrode, though various methods are adopted depending upon the material, the method can be selected taking into consideration the adaptability to the electrode material. Specifically, the pixel electrode and the counter electrode can be formed by a wet system such as a printing system and a coating system, a physical system such as a vacuum vapor deposition method, a sputtering method, and an ion plating method, or a chemical system such as a CVD method and a plasma CVD method. In the case of ITO, the layer is formed by a method such as an electron beam method, a sputtering method, a resistance heating vapor deposition method, a chemical reaction method (for example, a sol-gel method), and coating of a dispersion of indium tin oxide. In the case of ITO, a UV-ozone treatment, a plasma treatment, or the like can be applied.

In the invention, it is preferable that the transparent electrode layer is fabricated in a plasma-free state. By fabricating the transparent electrode layer in a plasma-free state, it is possible to minimize influences of the plasma to the substrate and to make the photoelectric conversion characteristics good. The plasma-free state as referred to herein means a state where a plasma is not generated during the deposition of a transparent electrode layer, or a distance from a plasma generation source to the substrate is 2 cm or more, preferably 10 cm or more, and still more preferably 20 cm or more, thereby reducing the plasma reaching the substrate.

Examples of a device in which plasma is not generated during the deposition of a transparent electrode layer include an electron beam vapor deposition apparatus (EB vapor deposition apparatus) and a pulse laser vapor deposition apparatus. As for the EB vapor deposition apparatus or pulse laser vapor deposition apparatus, apparatuses described in Developments of Transparent Conducting Films, supervised by Yutaka Sawada (published by CMC Publishing Co., Ltd., 1999); Developments of Transparent Conducting Films II, supervised by Yutaka Sawada (published by CMC Publishing Co., Ltd., 2002); Technologies of Transparent Conducting Films, written by Japan Society for the Promotion of Science (published by Ohmsha, Ltd., 1999); and references as added therein can be used. In the following, the method for achieving deposition of a transparent electrode layer using an EB vapor deposition apparatus is referred to as “EB vapor deposition method”; and the method for achieving deposition of a transparent electrode layer using a pulse laser vapor deposition apparatus is referred to as “pulse laser vapor deposition method”. As for the apparatus capable of realizing the state where a distance from the plasma generation source to the substrate is 2 cm or more, and the plasma reaching the substrate is reduced (hereinafter referred to as “plasma-free deposition apparatus”), for example, a counter target type sputtering apparatus and an arc plasma vapor deposition method may be thought. As for these matters, apparatuses described in Developments of Transparent Conducting Films, supervised by Yutaka Sawada (published by CMC Publishing Co., Ltd., 1999); Developments of Transparent Conducting Films II, supervised by Yutaka Sawada (published by CMC Publishing Co., Ltd., 2002); Technologies of Transparent Conducting Films, written by Japan Society for the Promotion of Science (published by Ohmsha, Ltd., 1999); and references as added therein can be used.

The electrode of the organic electromagnetic wave absorption/photoelectric conversion site according to the invention is hereunder described in more detail. The photoelectric conversion layer of an organic layer is interposed between a pixel electrode layer and a counter electrode layer and can contain an interelectrode material or the like. The “pixel electrode layer” as referred to herein refers to an electrode layer fabricated above a substrate in which a charge accumulation/transfer/read-out site is formed and is usually divided for every one pixel. This is made for the purpose of obtaining an image by reading out a signal charge which has been converted by the photoelectric conversion layer on a charge accumulation/transfer/signal read-out circuit substrate for every one pixel. The “counter electrode layer” as referred to herein has a function to discharge a signal charge having a reversed polarity to a signal charge by interposing the photoelectric conversion layer together with the pixel electrode layer. Since this discharge of a signal charge is not required to be divided among the respective pixels, the counter electrode layer can be usually made common among the respective pixels. Accordingly, the counter electrode layer is sometimes called a common electrode layer.

The photoelectric conversion layer is positioned between the pixel electrode layer and the counter electrode layer. The photoelectric conversion function functions by the pixel electrode layer and the counter electrode layer as well as this photoelectric convention layer.

As examples of the configuration of the photoelectric conversion layer stack, first of all, in the case where one organic layer is stacked on a substrate, there is enumerated a configuration in which a pixel electrode layer (basically a transparent electrode layer), a photoelectric conversion layer, and a counter electrode layer (transparent electrode layer) are stacked in this order from the substrate. However, it should not be construed that the invention is limited thereto.

Furthermore, in the case where two organic layers are stacked on a substrate, for example, there is enumerated a configuration in which a pixel electrode layer (basically a transparent electrode layer), a photoelectric conversion layer, a counter electrode layer (transparent electrode layer), an interlaminar insulating layer, a pixel electrode layer (basically a transparent electrode layer), a photoelectric conversion layer, and a counter electrode layer (transparent electrode layer) are stacked in this order from the substrate.

As the material of the transparent electrode layer constituting the photoelectric conversion site according to the invention, materials which can be deposited by a plasma-free deposition apparatus, EB vapor deposition apparatus or pulse laser vapor deposition apparatus. For example, metals, alloys, metal oxides, metal nitrides, metal borides, organic electrically conductive compounds, and mixtures thereof are suitably enumerated. Specific examples thereof include electrically conductive metal oxides such as tin oxide, zinc oxide, indium oxide, indium zinc oxide (IZO), indium tin oxide (ITO), and indium tungsten oxide (IWO); metal nitrides such as titanium nitride; metals such as gold, platinum, silver, chromium, nickel, and aluminum; mixtures or stacks of such a metal and such an electrically conductive metal oxide; inorganic electrically conductive substances such as copper iodide and copper sulfide; organic electrically conductive materials such as polyaniline, polythiophene, and polypyrrole; and stacks thereof with ITO. In addition, materials described in detail in Developments of Transparent Conducting Films, supervised by Yutaka Sawada (published by CMC Publishing Co., Ltd., 1999); Developments of Transparent Conducting Films II, supervised by Yutaka Sawada (published by CMC Publishing Co., Ltd., 2002); Technologies of Transparent Conducting Films, written by Japan Society for the Promotion of Science (published by Ohmsha, Ltd., 1999); and references as added therein may be used.

As the material of the transparent electrode layer, any one material of ITO, IZO, SnO₂, ATO (antimony-doped tin oxide), ZnO, AZO (Al-doped zinc oxide), GZO (gallium-doped zinc oxide), TiO₂, or FTO (fluorine-doped tin oxide) is especially preferable.

A light transmittance of the transparent electrode layer is preferably 60% or more, more preferably 80% or more, still more preferably 90% or more, and yet still more preferably 95% or more at a photoelectric conversion light absorption peak wavelength of the photoelectric conversion layer which is included in a photoelectric conversion device including that transparent electrode layer. In addition, as for a surface resistance of the transparent electrode layer, its preferred range varies depending upon whether the transparent electrode layer is a pixel electrode or a counter electrode, whether the charge accumulation/transfer/read-out site is of a CCD structure or a CMOS structure, or the like. In the case where the transparent electrode layer is used for a counter electrode, and the charge accumulation/transfer/read-out site is of a CMOS structure, the surface resistance of the transparent electrode layer is preferably not more than 10,000Ω/□, and more preferably not more than 1,000Ω/□. In the case where the transparent electrode layer is used for a counter electrode, and the charge accumulation/transfer/read-out site is of a CCD structure, the surface resistance of the transparent electrode layer is preferably not more than 1,000Ω/□, and more preferably not more than 100Ω/□. In the case where the transparent electrode layer is used for a pixel electrode, the surface resistance of the transparent electrode layer is preferably not more than 1,000,000Ω/□ and more preferably not more than 100,000Ω/□.

Conditions at the time of deposition of a transparent electrode layer are hereunder mentioned. A substrate temperature at the time of deposition of a transparent electrode layer is preferably not higher than 500° C., more preferably not higher than 300° C., still more preferably not higher than 200° C., and yet still further preferably not higher than 150° C. In addition, a gas may be introduced during the deposition of a transparent electrode layer. Basically, though the gas species is not limited, Ar, He, oxygen, nitrogen, and the like can be used. In addition, a mixed gas of such gases may be used. In particular, in the case of an oxide material, since oxygen deficiency often occurs, it is preferable to use oxygen.

### (Inorganic Layer)

An inorganic layer as the electromagnetic wave absorption/photoelectric conversion site is hereunder described. In that case, light which has passed through the organic layer as the upper layer is subjected to photoelectric conversion in the inorganic layer. As for the inorganic layer, pn junction or pin junction of crystalline silicon, amorphous silicon, or a chemical semiconductor such as GaAs is generally used. As for the stack type structure, a method disclosed in U.S. Pat. No. 5,965,875 can be adopted. That is, a configuration in which a light receiving part as stacked by utilizing wavelength dependency of a coefficient of absorption of silicon is formed, and color separation is carried out in a depth direction thereof. In that case, since the color separation is carried out in a light penetration depth of silicon, a spectrum range as detected in each of the stacked light receiving parts becomes broad. However, by using the foregoing organic layer as the upper layer, namely by detecting the light which has transmitted through the organic layer in the depth direction of silicon, the color separation is remarkably improved. In particular, when a G layer is disposed in the organic layer, light which has transmitted through the organic layer becomes B light and R light, and therefore, only BR lights are subjective to separation of light in the depth direction in silicon, and the color separation is improved. Even in the case where the organic layer is a B layer or an R layer, by properly selecting the electromagnetic wave absorption/photoelectric conversion site of silicon in the depth direction, the color separation is remarkably improved. In the case where the organic layer is made of two layers, the function as the electromagnetic wave absorption/photoelectric conversion site of silicon may be brought for only one color, and preferred color separation can be achieved.

The inorganic layer preferably has a structure in which plural photodiodes are superposed for every pixel in a depth direction within the semiconductor substrate, and a color signal according to a signal charge generated in each of the photodiodes by light to be absorbed in the foregoing plural photodiodes is read out into the external. Preferably, the foregoing plural photodiodes contain at least one of a first photodiode which is provided in the depth for absorbing B light and a second photodiode which is provided in the depth for absorbing R light and are provided with a color signal read-out circuit for reading out a color signal according to the foregoing signal charge generated in each of the foregoing plural photodiodes. According to this configuration, it is possible to carry out color separation without using a color filter. In addition, under some circumstances, since light of a negative sensitive component can also be detected, it becomes possible to realize color imaging with good color reproducibility. In addition, in the invention, it is preferable that a junction part of the foregoing first photodiode is formed in a depth of up to about 0.2 μm from the semiconductor substrate surface and that a junction part of the foregoing second photodiode is formed in a depth of up to about 2 μm from the semiconductor substrate surface.

The inorganic layer is hereunder described in more detail. Preferred examples of the configuration of the inorganic layer include a photoconductive type, a p-n junction type, a shotkey junction type, a PIN junction type, a light receiving device of an MSM (metal-semiconductor-metal) type, and a light receiving device of a phototransistor type. In the invention, it is preferable to use a light receiving device in which a plural number of a first electrically conductive type region and a second electrically conductive type region which is a reversed electrically conductive type to the first electrically conductive type are alternately stacked within a single semiconductor substrate, and each of the junction planes of the first electrically conductive type region and the second electrically conductive type region is formed in a depth suitable for subjecting mainly plural lights of a different wavelength region to photoelectric conversion. The single semiconductor substrate is preferably monocrystalline silicon, and the color separation can be carried out by utilizing absorption wavelength characteristics which rely upon the depth direction of the silicon substrate.

As the inorganic semiconductor, an InGaN based, InAlN based, InAlP based, or InGaAlP based inorganic semiconductor can also be used. The InGaN based inorganic semiconductor is an inorganic semiconductor which is adjusted so as to have a maximum absorption value within a blue wavelength range by properly changing the In-containing composition. That is, the composition becomes InₓGa₁₋ₓN (0<x<1).

Such a compound semiconductor is manufactured by adopting a metal organic chemical vapor deposition method (MOCVD method). As for the InAlN based nitride semiconductor using, as a raw material, Al of the Group 13 similar to Ga, it can be used as a short wavelength light receiving part similar to the InGaN based semiconductor. In addition, InAlP or InGaAlP lattice-matching with a GaAs substrate can also be used.

The inorganic semiconductor may be of a buried structure. The “buried structure” as referred to herein refers to a configuration in which the both ends of a short wavelength light receiving part are covered by a semiconductor different from the short wavelength light receiving part. The semiconductor for covering the both ends is preferably a semiconductor having a band gap wavelength shorter than or equal to a hand gap wavelength of the short wavelength light receiving part.

The organic layer and the inorganic layer may be bound to each other in any form. In addition, for the purpose of electrically insulating the organic layer and the inorganic layer from each other, it is preferable to provide an insulating layer therebetween.

As for the junction, npn junction or pnpn junction from the light incident side is preferable. In particular, the pnpn junction is more preferable because by providing a p layer on the surface and increasing a potential of the surface, it is possible to trap a hole generated in the vicinity of the surface and a dark current and to reduce the dark current.

In such a photodiode, when an n-type layer, a p-type layer, an n-type layer, and a p-type layer which are successively diffused from the p-type silicon substrate surface are deeply formed in this order, the pn junction diode is formed of four layers of pnpn in a depth direction of silicon. As for the light which has come into the diode from the surface side, the longer the wavelength, the deeper the light penetration is, and the incident wavelength and the attenuation coefficient exhibit values inherent to silicon. Accordingly, the photodiode is designed in such a manner that the depth of the pn junction plane covers respective wavelength bands of visible light. Similarly, a junction diode of three layers of npn is obtained by forming an n-type layer, a p-type layer, and n-type layer in this order. Here, a light signal is collected from the n-type layer, and the p-type layer is connected to a ground wire. In addition, when a collection electrode is provided in each region, and a prescribed reset potential is impressed, each region is depleted, and the capacity of each junction part becomes small unlimitedly. In this way, it is possible to make the capacity generated on the junction plane extremely small.

### (Auxiliary Layer)

In the invention, preferably, an ultraviolet light absorption layer and/or an infrared light absorption layer is provided in an uppermost layer of the electromagnetic wave absorption/photoelectric conversion site. The ultraviolet light absorption layer is able to at least absorb or reflect light of not more than 400 nm, and it preferably has an absorption factor of 50% or more in a wavelength region of not more than 400 nm. The infrared light absorption layer is able to at least absorb or reflect light of 700 nm or more, and it preferably has an absorption factor of 50% or more in a wavelength region of 700 nm or more.

Such an ultraviolet light absorption layer or infrared light absorption layer can be formed by a conventionally known method. For example, there is known a method in which a mordant layer made of a hydrophilic polymer substance such as gelatin, casein, glue, and polyvinyl alcohol is provided on a substrate, and a dye having a desired absorption wavelength is added to or dyes the mordant layer to form a colored layer. Furthermore, there is known a method of using a colored resin having a certain kind of coloring material dispersed in a transparent resin. For example, it is possible to use a colored resin layer having a coloring material mixed in a polyamino based resin, as described in JP-A-58-46325, JP-A-60-78401, JP-A-60-184202, JP-A-60-184203, JP-A-60-184204, and JP-A-60-184205. It is also possible to use a coloring agent using a polyamide resin having photosensitivity.

It is also possible to disperse a coloring material in an aromatic polyamide resin having a photosensitive group in a molecule thereof and capable of obtaining a cured layer at not higher than 200° C., as described in JP-B-7-113685 and to use a colored resin having a pigment dispersed therein, as described in JP-B-7-69486.

In the invention, a dielectric multilayer layer is preferably used. The dielectric multilayer layer has sharp wavelength dependency of light transmission and is preferably used.

It is preferable that the respective electromagnetic wave absorption/photoelectric conversion sites are separated by an insulating layer. The insulating layer can be formed by using a transparent insulating material such as glass, polyethylene, polyethylene terephthalate, polyethersulfone, and polypropylene. Silicon nitride, silicon oxide, and the like are also preferably used. Silicon nitride prepared by deposition by means of plasma CVD is preferably used in the invention because it is high in compactness and good in transparency.

For the purpose of preventing contact with oxygen, moisture, etc., a protective layer or a sealing layer can be provided, too. Examples of the protective layer include a diamond thin film, an inorganic material layer made of a metal oxide, a metal nitride, etc., a polymer layer made of a fluorine resin, poly-p-xylene, polyethylene, a silicone resin, a polystyrene resin, etc., and a layer made of a photocurable resin. In addition, it is also possible to cover a device portion by glass, a gas-impermeable plastic, a metal, etc. and package the device itself by a suitable sealing resin. In that case, it is also possible to make a substance having high water absorption properties present in a packaging.

Furthermore, condensation efficiency can be enhanced by forming a microlens array above a light receiving device, and therefore, such an embodiment is preferable, too.

### (Charge Accumulation/Transfer/Read-Out Site)

As for the charge accumulation/transfer/read-out site, JP-A-58-103166, JP-A-58-103165, JP-A-2003-332551, and the like can be made hereof by reference. A configuration in which an MOS transistor is formed on a semiconductor substrate for every pixel unit or a configuration having CCD as a device can be properly adopted. For example, in the case of a photoelectric conversion device using an MOS transistor, a charge is generated in a photoelectric conversion layer by incident light which has transmitted through electrodes; the charge runs to the electrodes within the photoelectric conversion layer by an electric field generated between the electrodes by impressing voltage to the electrodes; and the charge is further transferred to a charge accumulating part of the MOS transistor and accumulated in the charge accumulating part. The charge accumulated in the charge accumulating part is transferred to a charge read-out part by switching of the MOS transistor and further outputted as an electric signal. In this way, full-color image signals are inputted in a solid-state imaging apparatus including a signal processing part.

It is possible to read out the signal charge after injecting a fixed amount of bias charge into the accumulation diode (refresh mode) and then accumulating a fixed amount of the charge (photoelectric conversion mode). The light receiving device itself can also be used as the accumulation diode, or an accumulation diode can also be separately provided.

The read-out of the signal is hereunder described in more detail. The read-out of the signal can be carried out by using a usual color read-out circuit. A signal charge or a signal current which has been subjected to photoelectric conversion in the light receiving part is accumulated in the light receiving part itself or a capacitor as provided. The accumulated charge is subjected to selection of a pixel position and read-out by a technique of an MOS type imaging device (so-called CMOS sensor) using an X-Y address system. Besides, as an address selection system, there is enumerated a system in which every pixel is successively selected by a multiplexer switch and a digital shift register and read out as a signal voltage (or charge) on a common output line. An imaging device of a two-dimensionally arrayed X-Y address operation is known as a CMOS sensor. In this imaging device, a switch which is provided in a pixel connected to an X-Y intersection point is connected to a vertical shift register, and when the switch is turned on by voltage from the vertical scanning shift register, signals read out from pixels which are provided in the same row are read out on the output line in a column direction. The signals are successively read out from an output end through the switch to be driven by a horizontal scanning shift register.

For reading out the output signals, a floating diffusion detector or a floating gate detector can be used. In addition, it is possible to contrive to enhance S/N by a technique such as provision of a signal amplification circuit in the pixel portion and correlated double sampling.

For the signal processing, gamma correction by an ADC circuit, digitalization by an AD transducer, luminance signal processing, and color signal processing can be applied. Examples of the color signal processing include white balance processing, color separation processing, and color matrix processing. In using for an NTSC signal, RGB signals can be subjected to conversion processing of YIQ signals.

The charge transfer/read-out site is required to have a mobility of charge of 100 cm²/vol·sec or more. This mobility can be obtained by selecting the material among semiconductors of the IV group, the III-V group, or the II-VI group. Above all, silicon semiconductors (also referred to as “Si semiconductors”) are preferable because of advancement of a microstructure refinement technology and low costs. As for the charge transfer/charge read-out system, there are made a large number of proposals, and all of them are adoptable. Above all, a COMS type or CCD type device is an especially preferred system. Furthermore, in the case of the invention, in many occasions, the CMOS type device is preferable in view of high-speed read-out, pixel addition, partial read-out, and consumed electricity.

### (Connection)

Though plural contact sites for connecting the electromagnetic wave absorption/photoelectric conversion site to the charge transfer/read-out site may be connected by any metal, a metal selected among copper, aluminum, silver, gold, chromium, and tungsten is preferable, and copper is especially preferable. According to the plural electromagnetic wave absorption/photoelectric conversion sites, each of the contact sites is required to be placed between the electromagnetic wave absorption/photoelectric conversion site and the charge transfer/read-out site. In the case of taking a stacked structure of plural photosensitive units of blue, green and red lights, a blue light collection electrode and the charge transfer/read-out site, a green light collection electrode and the charge transfer/read-out site, and a red light collection electrode and the charge transfer/read-out site are required to be connected, respectively.

### (Process)

The stacked photoelectric conversion device according to the invention can be manufactured according to a so-called known microfabrication process which is adopted in manufacturing integrated circuits and the like. Basically, this process is concerned with a repeated operation of pattern exposure with active light, electron beams, etc. (for example, i- or g-bright line of mercury, excimer laser, X-rays, and electron beams), pattern formation by development and/or burning, alignment of device forming materials (for example, coating, vapor deposition, sputtering, and CV), and removal of the materials in a non-pattern area (for example, heat treatment and dissolution treatment).

### (Utility)

A chip size of the device can be selected among a brownie size, a 135 size, an APS size, a 1/1.8-inch size, and a smaller size. A pixel size of the stacked photoelectric conversion device according to the invention is expressed by a circle-corresponding diameter which is corresponding to a maximum area in the plural electromagnetic absorption/photoelectric conversion sites. Though the pixel size is not limited, it is preferably from 2 to 20 microns, more preferably from 2 to 10 microns, and especially preferably from 3 to 8 microns.

When the pixel size exceeds 20 microns, a resolving power is lowered, whereas when the pixel size is smaller than 2 microns, the resolving power is also lowered due to radio interference between the sizes.

The stacked photoelectric conversion device according to the invention can be utilized for a digital still camera. In addition, it is preferable that the photoelectric conversion device according to the invention is used for a TV camera. Besides, the photoelectric conversion device according to the invention can be utilized for a digital video camera, a monitor camera (in, for example, office buildings, parking lots, unmanned loan-application systems in financial institution, shopping centers, convenience stores, outlet malls, department stores, pachinko parlors, karaoke boxes, game centers, and hospitals), other various sensors (for example, TV door intercoms, individual authentication sensors, sensors for factory automation, robots for household use, industrial robots, and piping examination systems), medical sensors (for example, endoscopes and fundus cameras), videoconference systems, television telephones, camera-equipped mobile phones, automobile safety running systems (for example, back guide monitors, collision prediction systems, and lane-keeping systems), and sensors for video game.

Above all, the photoelectric conversion device according to the invention is suitable for use of a television camera. The reason for this resides in the matter that since it does not require a color decomposition optical system, it is able to achieve miniaturization and weight reduction of the television camera. In addition, since the photoelectric conversion device according to the invention has high sensitivity and high resolving power, it is especially preferable for a television camera for high-definition broadcast. In that case, the term “television camera for high-definition broadcast” as referred to herein includes a camera for digital high-definition broadcast.

Furthermore, the photoelectric conversion device according to the invention is preferable because an optical low pass filter can be omitted, and higher sensitivity and higher resolving power can be expected.

Furthermore, in the photoelectric conversion device according to the invention, not only the thickness can be made thin, but a color decomposition optical system is not required. Therefore, as for shooting scenes in which a different sensitivity is required, such as “circumstances with a different brightness such as daytime and nighttime” and “immobile subject and mobile subject” and other shooting scenes in which requirements for spectral sensitivity or color reproducibility differ, various needs for shooting can be satisfied by a single camera by exchanging the photoelectric conversion device according to the invention and performing shooting. At the same time, it is not required to carry plural cameras. Thus, a load of a person who wishes to take a shot is reduced. As a photoelectric conversion device which is subjective to the exchange, in addition to the foregoing, exchangeable photoelectric conversion devices for purposes of infrared light shooting, black-and-white shooting, and change of a dynamic range can be prepared.

The TV camera according to the invention can be prepared by referring to a description in Chapter 2 of Design Technologies of Television Camera, edited by the Institute of Image Information and Television Engineers (Aug. 20, 1999, published by Corona Publishing Co., Ltd., ISBN 4-339-00714-5) and, for example, replacing a color decomposition optical system and an imaging device as a basic configuration of a television camera as shown in FIG. 2.1 thereof by the photoelectric conversion device according to the invention.

By arraying the foregoing stacked light receiving device, it can be utilized not only as an imaging device but as an optical sensor such as biosensors and chemical sensors or a color light receiving device in a single body.

### (Preferred Photoelectric Conversion Device According to the Invention)

The photoelectric conversion devices can be roughly classified into a photocell and a photosensor, and the photoelectric conversion devices shown in FIG. 1B and FIG. 1C are suitable for a photosensor. The photosensor may be a sensor using a photoelectric conversion device alone, or may be in a form of a line sensor in which photoelectric conversion devices are linearly arranged, or a two-dimensional sensor in which photoelectric conversion devices are arranged on a plane surface.

In the line sensor, the optical image information is converted into electric signals by using an optical system and a driving unit as in a scanner and the like, and in the two-dimensional sensor, the optical image information is imaged on the sensor by an optical system and converted into electric signals as in an imaging module, thereby effecting the function as an imaging device.

The photocell (solar cell) is power-generating equipment, and therefore, the efficiency of converting light energy into electrical energy is an important performance. However, the dark current that is a current in the dark place does not become a problem in view of a function of the photocell. In addition, unlike the imaging device, a color filter need not be provided, and therefore, a heating step in a later stage is not required.

In the photosensor, the performance of converting light-dark signals into electric signals with high precision is important, and therefore, the efficiency of converging the light quantity into a current is also an important performance. Moreover, unlike the photocell, a signal outputted in the dark place works out to a noise deteriorating the image, and therefore, a low dark current is required. Furthermore, durability against a manufacturing step in a later stage such as stacking of a color filter is also important.

An embodiment of the invention is hereunder described by reference to the accompanying drawings.

First of all, for reference, FIG. 1A is a diagrammatic cross-section view of a photoelectric conversion device which is used in a solar cell or the like. A photoelectric conversion device 10a shown in FIG. 1A is constituted of an electrically conductive layer 11 functioning as a lower electrode, a transparent electrically conductive layer 15 functioning as an upper electrode (the light incident side is defined as an “upper part”), and a photoelectric conversion layer (also called an organic photoelectric conversion layer) 12 formed between the upper electrode 15 and the lower electrode 11, and stacking is made in the order of the lower electrode 11, the photoelectric conversion layer 12, and the upper electrode 15.

FIG. 1B is a diagrammatic cross-sectional view of a photoelectric conversion device which is used in an imaging device. This photoelectric conversion device 10b has a configuration in which an electron blocking layer 16A is added between the lower electrode 11 and the photoelectric conversion layer 12 relative to the photoelectric conversion device 10a shown in FIG. 1A, and stacking is made in the order of the lower electrode 11, the electron blocking layer 16A, the photoelectric conversion layer 12, and the upper electrode 15.

The imaging device according to the invention is provided with the photoelectric conversion device according to the invention.

FIG. 1C is a diagrammatic cross-sectional view of a photoelectric conversion device according to a first embodiment of the invention, which is used in an imaging device. This photoelectric conversion device 10C has a configuration in which a hole blocking layer 16B is added between the upper electrode 15 and the photoelectric conversion layer 12 relative to the photoelectric conversion device 10b shown in FIG. 1B, and stacking is made in the order of the lower electrode 11, the electron blocking layer 16A, the photoelectric conversion layer 12, the hole blocking layer 16B, and the upper electrode 15.

Incidentally, in each of the photoelectric conversion devices 10a, 10b and 10c, the order of stacking of the lower electrode 11, the electron blocking layer 16A, the organic photoelectric conversion layer 12, the hole blocking layer 16B, and the upper electrode 12 may be made reversed according to the utility or characteristics of the photoelectric conversion device. In that case, it would be better that the electrode (electrically conductive layer) on the side through which light transmits is constituted of a transparent material.

In addition, in the case of using such a photoelectric conversion device, it is preferable to impress an electric field between the upper electrode 15 and the lower electrode 11. For example, an arbitrary prescribed electric field can be impressed within the range of 1×10⁻⁴ V/cm or more and not more than 1×10⁷ V/cm between a pair of the electrodes. The electric field to be impressed is preferably 1×10⁻¹ V/cm or more and not more than 5×10⁶ V/cm, more preferably 1×10² V/cm or more and not more than 3×10⁶ V/cm, and especially preferably 1×10⁵ V/cm or more and not more than 1×10⁶ V/cm.

Constituent materials of each of the photoelectric conversion devices 10a, 10b and 10c are hereunder described.

Each of the upper electrode (transparent electrically conductive layer) 15 and the lower electrode (electrically conductive layer) 11 is constituted of an electrically conductive material. As for the electrically conductive material, those described above in the section of (Electrode) are preferable.

Above all, electrically conductive metal oxides are preferable for the upper electrode 15 from the standpoints of high electric conductivity, transparency, and the like. Since the upper electrode 15 is deposited on the organic photoelectric conversion layer 12, it is preferable to carry out the deposition of the upper electrode 15 by a method in which the characteristics of the organic photoelectric conversion layer 12 are not deteriorated. In addition, the upper electrode 15 is preferably made of a transparent electrically conductive oxide.

As for the lower electrode 11, there may be the case where transparency is brought, or the case where a material for reversely reflecting light without bringing transparency is used, depending upon the utility. Specifically, those described above in the section of (Electrode) are preferable.

In the case where the upper electrode 15 is a transparent electrically conductive layer such as TCO, there may be the case where a DC short or an increase of leak current occurs. One of causes thereof is considered to reside in the matter that fine cracks introduced into the photoelectric conversion layer 12 are subjected to coverage by a dense layer such as TCO to increase the conduction with the electrode 11 on the opposite side. Therefore, in the case of an electrode having relatively poor film quality such as aluminum, the leak current hardly increases. The increase of leak current can be greatly suppressed by controlling a layer thickness of the upper electrode 15 relative to a layer thickness (that is, the crack depth) of the photoelectric conversion layer 12. It is desirable that the thickness of the upper electrode 15 is preferably not more than ⅕, and more preferably not more than 1/10 of the thickness of the photoelectric conversion layer 12.

In addition, the thinner the thickness of the upper electrode (transparent electrically conductive layer) 15, the smaller the amount of absorbed light is, and in general, the light transmittance increases. The increase of the light transmittance is very preferable because the light absorption in the photoelectric conversion layer 12 is increased, and the photoelectric conversion ability is increased. When the suppression of leak current, the increase of a resistivity value of the thin layer, and the increase of the light transmittance, all of which are brought following the thinning of the layer, are taken into consideration, it is desirable that the layer thickness of the upper electrode 15 is preferably from 5 to 100 nm, and more preferably from 5 to 20 nm.

FIG. 2 is a schematic cross-sectional view of a one-pixel portion of an imaging device according to a second embodiment of the invention using the photoelectric conversion device explained in FIG. 1C. As for the term “one-pixel” as referred to herein, a pixel capable of obtaining signals of three colors of RGB is made a unit. Incidentally, in configuration examples as described below, members and the like having the same configurations and actions as those in the members and the like explained in FIG. 1A, FIG. 1B, and FIG. 1C are given the same symbols or corresponding symbols in the drawings, thereby simplifying or omitting their explanations.

The imaging device as referred to herein is a device for converting optical information of an image into electric signals, in which plural photoelectric conversion devices are disposed in a matrix state on the same plane, an optical signal is converted into an electric signal in each of the photoelectric conversion devices (pixels), and the electric signal is able to be successively outputted into the external for every pixel. For that reason, the imaging device is constituted of one photoelectric conversion device and one or more transistors per pixel.

An imaging device 100 shown in FIG. 2 is an imaging device in which a large number of pixels each constituting one pixel are disposed in an array state on the same plane, and one-pixel data of image data can be formed by a single obtained by this one pixel.

The imaging device 100 is provided with an n-type silicon substrate 1 and a transparent insulating layer 7 formed on the n-type silicon substrate 1, and the photoelectric conversion device 10b or 10c explained in FIG. 1B or FIG. 1C is formed on the insulating layer 7. In the photoelectric conversion device shown in FIG. 2, the symbols are expressed by a lower electrode 101, a photoelectric conversion layer 102, and an upper electrode 104. In addition, in FIG. 2, illustration of an electron blocking layer and a hole blocking layer is omitted.

A light-shielding layer 114 having an opening 114a provided therein is formed on the photoelectric conversion device 10b (10c), and a transparent insulating layer 115 is formed on the upper electrode 104 on the opening 114a and on the light-shielding layer 114.

Just under the opening 114a of the surface part of the n-type silicon substrate 1, a p-type impurity region (hereinafter abbreviated as “p region”) 4, an n-type impurity region (hereinafter abbreviated as “n region”) 3, and a p region 2 are formed in this order from the shallow side thereof. A high-density p region 6 is formed in the surface part of a portion of the p region 4 light-shielded by the light-shielding layer 114, and the periphery of the p region 6 is surrounded by an n region 5.

The depth of the pn junction plane between the p region 4 and the n region 3 from the surface of the n-type silicon substrate 1 is a depth (about 0.2 μm) for absorbing blue light. Accordingly, the p region 4 and the n region 3 absorb the blue light to form a photodiode (B photodiode) capable of accumulating a charge corresponding thereto.

The depth of the pn junction plane between the p region 2 and the n-type silicon substrate 1 from the surface of the n-type silicon substrate 1 is a depth (about 2 μm) for absorbing red light. Accordingly, the p region 2 and the n-type silicon substrate 1 absorb the red light to form a photodiode (R photodiode) capable of accumulating a charge corresponding thereto.

The p region 6 is electrically connected to the lower electrode 101 via a connection part 9 formed in the opening bored in the insulating layer 7. A hole trapped by the lower electrode 101 recombines with an electron in the p region 6, and therefore, the number of electrons accumulated in the p region 6 at the time of resetting decreases according to the number of trapped holes. The outer peripheral surface of the connection part 9 is covered by an insulating layer 8, and the connection part 9 is electrically insulated by the insulating layer 8 from portions exclusive of the lower electrode 101 and the p region 6.

The electrons accumulated in the p region 2 are converted into signals according to the charge amount by an MOS circuit (not shown) composed of a p-channel MOS transistor formed within the n-type silicon substrate 1; the electrons accumulated in the p region 4 are converted into signals according to the charge amount by an MOS circuit (not shown) composed of a p-channel MOS transistor formed within the n region 3; the electrons accumulated in the p region 6 are converted into signals according to the charge amount by an MOS circuit (not shown) composed of a p-channel MOS transistor formed within the n region 5; and these signals are outputted to the outside of the imaging device 100.

Each of the MOS circuits is connected to a signal read-out pad (not shown) by a wiring 113. Incidentally, when an extractor electrode is provided in the p region 2 and the p region 4, and a predetermined reset potential is applied, each of the regions 2 and 4 is depleted, and the capacitance of each of the pn junction parts becomes an infinitely small value, whereby the capacitance produced on the junction plane can be made extremely small.

Thanks to such a configuration, G (green) light can be subjected to photoelectric conversion by the photoelectric conversion layer 102, and B (blue) light and R (red) light can be subjected to photoelectric conversion by the B photodiode and the R photodiode, respectively in the n-type silicon substrate 1. In addition, since the G light is first absorbed above the semiconductor substrate, excellent color separation is achieved between B-G and between G-R by the B photodiode and the R photodiode, respectively formed in the semiconductor substrate.

This color separation performance is a greatly excellent point of the imaging device of the embodiment shown in FIG. 2 in comparison with an imaging device of the type in which three photodiodes inclusive of a G photodiode in addition to a B photodiode and an R photodiode are provided within a semiconductor substrate, and all of B light, G light, and R light are separated by the semiconductor substrate.

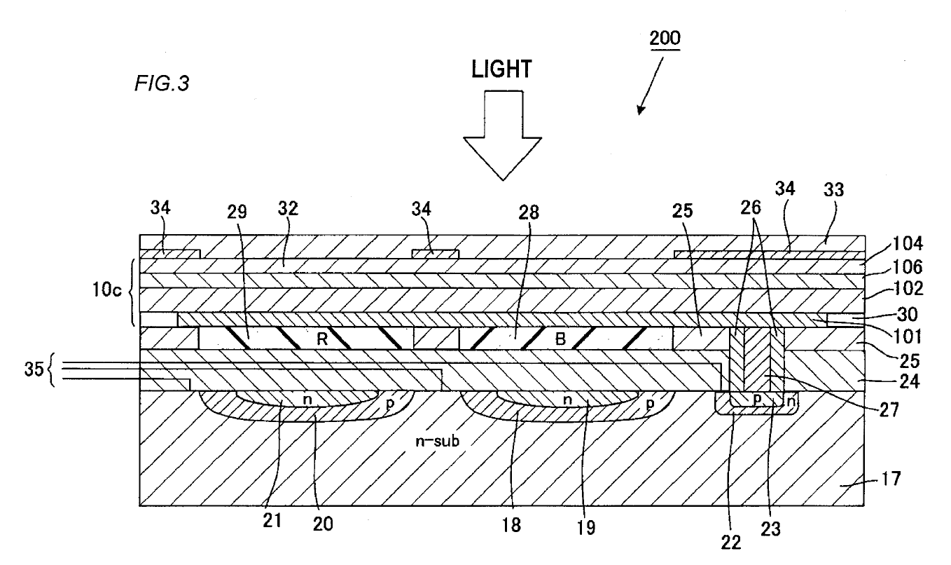

FIG. 3 is a schematic cross-sectional view of a one-pixel portion of an imaging device according to a third embodiment of the invention. Unlike the imaging device 100 shown in FIG. 2, having a configuration in which the two photodiodes are stacked within the semiconductor substrate 1, an imaging device 200 of the present embodiment has a configuration in which two photodiodes are arrayed in the direction perpendicular to the incident direction of incident light (namely, this perpendicular direction is the direction along the surface of the semiconductor substrate), thereby detecting lights of two colors within an n-type silicon substrate.

In FIG. 3, the imaging device 200 of the present embodiment is provided with an n-type silicon substrate 17 and a transparent insulating layer 24 stacked on the surface of the n-type silicon substrate 17, and the photoelectric conversion device 10c explained in FIG. 1C is stacked thereon. As for the symbols of the respective constituent members of the photoelectric conversion device 10c shown in FIG. 3, the lower electrode 101, the photoelectric conversion layer 102, and the upper electrode 104 are the same as those in FIG. 2, and though illustration of an electron blocking layer is omitted, the hole blocking layer 106 is shown. Incidentally, the photoelectric conversion device 10b shown in FIG. 1B may be adopted. A light-shielding layer 34 provided with openings is formed on the photoelectric conversion device 10c. In addition, a transparent insulating layer 33 is formed on the openings of the upper electrode 104 and the light-shielding layer 34.

In a surface part of the n-type silicon substrate 17 under the openings of the light-shielding layer 34, a photodiode composed of an n region 19 and a p region 18 and a photodiode composed of an n region 21 and a p resin 20 are allowed to lie in juxtaposition on the surface of the n-type silicon substrate 17. An arbitrary plane direction on the surface of the n-type silicon substrate 17 becomes the direction perpendicular to the incident direction of incident light.

Above the photodiode composed of the n region 19 and the p region 18, a color filter 28 through which B light transmits via the transparent insulating layer 24 is formed, and the lower electrode 101 is formed thereon. In addition, above the photodiode composed of the n region 21 and the p region 20, a color filter 29 through which R light transmits via the transparent insulating layer 24 is formed, and the lower electrode 101 is formed thereon. The surroundings of each of the color filters 28 and 29 are covered by a transparent insulating layer 25. Incidentally, a symbol 30 between the lower electrodes (pixel electrodes) 101 is an insulating layer for separating the pixel electrodes from each other.

The photodiode composed of the n region 19 and the p region 18 functions as an in-substrate photoelectric conversion part that absorbs B light having transmitted through the color filter 28, generates electrons corresponding thereto, and accumulates the generated electrons in the p region 18. The photodiode composed of the n region 21 and the p region 20 functions as an in-substrate photoelectric conversion part that absorbs R light having transmitted through the color filter 29, generates electrons corresponding thereto, and accumulates the generated electrons in the p region 20.

In the portion light-shielded by the light-shielding layer 34 on the surface of the n-type silicon substrate 17, a p region 23 is formed, and the periphery of the p region 23 is surrounded by an n region 22.

The p region 23 is electrically connected to the lower electrode 101 via a connection part 27 formed within the opening bored in the insulating layers 24 and 25. A hole generated in the photoelectric conversion layer 102 and trapped by the lower electrode 101 recombines with an electron in the p region 23 through a connection part 27, and therefore, the number of electrons accumulated in the p region 23 at the time of resetting decreases according to the number of trapped holes. The periphery of the connection part 27 is surrounded by an insulating layer 26, and the connection part 27 is electrically insulated from portions exclusive of the lower electrode 101 and the p region 23.

The electrons accumulated in the p region 18 are converted into signals according to the charge amount by an MOS circuit (not shown) composed of a p-channel MOS transistor formed within the n-type silicon substrate 17, and the electrons accumulated in the p region 20 are converted into signals according to the charge amount by an MOS circuit (not shown) composed of a p-channel MOS transistor formed within the n-type silicon substrate 17. Similarly, the electrons accumulated in the p region 23 are converted into signals according to the charge amount by an MOS circuit (not shown) composed of an n-channel MOS transistor formed within the n region 22. The respective converted signals are outputted to the outside of the imaging device 200. Each of the MOS circuits is connected to a signal read-out pad (not shown) by a wiring 35.

Incidentally, instead of MOS circuits, the foregoing signal read-out circuit composed of MOS transistors may be composed of CCD and an amplifier. Namely, the signal read-out circuit may be constituted in such a manner that electrons accumulated in the p region 18, the p region 20, and the p region 23 are respectively read out into CCD (charge transfer passage) formed within the n-type silicon substrate 17 and then transferred into an amplifier, and voltage value signals according to the amount of electrons are outputted as imaging image signals by the amplifier.

In this way, the signal read-out part includes a CCD structure and a CMOS structure. However, in view of power consumption, high-speed read-out, easiness of pixel addition, easiness of partial read-out, and the like, a CMOS type is preferable. Incidentally, in the imaging device 200 of FIG. 3, color separation of R light and B light is performed by the color filters 28 and 29, but instead of providing the color filters 28 and 29, each of the depth of the pn junction plane between the p region 20 and then region 21 and the depth of the pn junction plane between the p region 18 and the n region 19 may be adjusted to absorb R light and B light by the respective photodiodes.

It is also possible to form an inorganic photoelectric conversion part composed of an inorganic material that absorbs light having transmitted through the photoelectric conversion layer 102, generates charges corresponding to the light, and accumulates the charges, between the n-type silicon substrate 17 and the lower electrode 101 (for example, between the insulating layer 24 and the n-type silicon substrate 17). In that case, an MOS circuit for reading out signals according to the charges accumulated in a charge accumulation region of the inorganic photoelectric conversion part may be provided within the n-type silicon substrate 17, and the wiring 35 may also be connected to this MOS circuit.

In addition, there may also be taken a configuration in which one photodiode is provided per pixel within the n-type silicon substrate 17, and a plurality of photoelectric conversion layers are stacked above the n-type silicon substrate 17. For example, a first photoelectric conversion layer for detecting a G signal by the photodiode and detecting an R signal and a second photoelectric conversion layer for detecting a B signal are stacked.

Furthermore, there may also be taken a configuration in which a plurality of photodiodes are provided per pixel within the n-type silicon substrate 17, and a plurality of photoelectric conversion layers are stacked above the n-type silicon substrate 17. For example, there may be taken a configuration in which an imaging device for detecting four colors including R, G, B, and emerald colors is formed by one pixel, and two colors are detected by the two photodiodes, and the remaining two colors are detected by two layers of the photoelectric conversion layers.

In addition, when a color image need not be formed, there may be taken a configuration in which one photodiode is provided per pixel within the n-type silicon substrate 17, and only one photoelectric conversion layer is stacked.

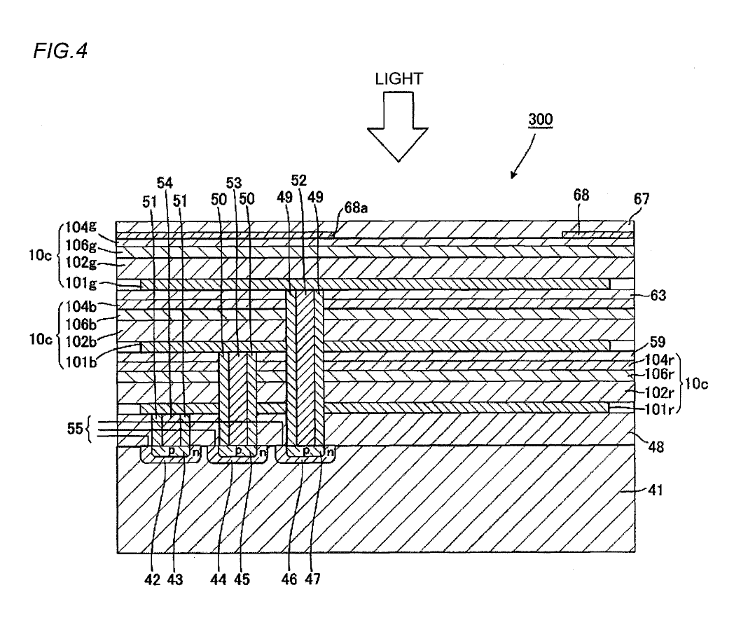

FIG. 4 is a schematic cross-sectional view of a one-pixel portion of an imaging device according to a fourth embodiment of the invention. An imaging device 300 of the present embodiment has a configuration in which signals of three colors of R, G and B are detected by three layers of photoelectric conversion layers provided above a silicon substrate, without providing a photodiode within the silicon substrate.

The imaging device 300 of the present embodiment has a configuration in which three photoelectric conversion layers inclusive of an R photoelectric conversion device for detecting R light, a B photoelectric conversion device for detecting G light, and a G photoelectric conversion device for detecting G light are stacked in this order above a silicon substrate 41. Each of the photoelectric conversion devices is made on the basis of the configuration shown in FIG. 1C. As for an organic photoelectric conversion dye which is used for the photoelectric conversion layer, a material capable of efficiently detecting the wavelength of light to be detected is used.

The R photoelectric conversion device is provided with a lower electrode 101r stacked above the silicon substrate 41 via an insulating layer 48, a photoelectric conversion layer 102r formed on the lower electrode 101r, a hole blocking layer 106r formed on the photoelectric conversion layer 102r, and an upper electrode 104r formed on the hole blocking layer 106r. Incidentally, the electron blocking layer illustrated in FIG. 1C is not shown in FIG. 4 (the same as in the following photoelectric conversion devices).

The B photoelectric conversion device is provided with a lower electrode 101b stacked on the upper electrode 104r of the R photoelectric conversion device via a transparent insulating layer 59, a photoelectric conversion layer 102b formed on the lower electrode 101b, a hole blocking layer 106b formed on the photoelectric conversion layer 102b, and an upper electrode 104b formed on the hole blocking layer 106b.

The G photoelectric conversion device is provided with a lower electrode 101g stacked on the upper electrode 104b of the B photoelectric conversion device via a transparent insulating layer 63, a photoelectric conversion layer 102g formed on the lower electrode 101g, a hole blocking layer 106g formed on the photoelectric conversion layer 102g, and an upper electrode 104g formed on the hole blocking layer 106g.

In this way, the imaging device 300 of the present embodiment has a configuration in which the R photoelectric conversion device, the B photoelectric conversion device, and the G photoelectric conversion device are stacked in this order on the silicon substrate 41.

On the upper electrode 104g of the G photoelectric conversion device stacked in the uppermost layer, a light-shielding layer 68 bored with an opening 68a is formed, and a transparent insulating layer 67 is formed so as to cover the upper electrode 104g exposed within the opening 68a and the light-shielding layer 68.

Materials of the lower electrode, the photoelectric conversion layer, and the upper electrode of each of the R, G and B photoelectric conversion devices are composed of the same materials as those in the foregoing embodiments. However, as described above, the photoelectric conversion layer 102g contains an organic material capable of absorbing green light and generating electrons and holes corresponding thereto, the photoelectric conversion layer 102b contains an organic material capable of absorbing blue light and generating electrons and holes corresponding thereto, and the photoelectric conversion layer 102r contains an organic material capable of absorbing red light and generating electrons and holes corresponding thereto.

In the portion light-shielded by the light-shielding film 68 on the surface of the silicon substrate 41, p regions 43, 45, and 47 are formed, and the peripheries of these regions are surrounded by n regions 42, 44, and 46, respectively.

The p region 43 is electrically connected to the lower electrode 101r via a connection part 54 formed within an opening bored in the insulating layer 48. A hole trapped by the lower electrode 101r recombines with an electron in the p region 43, and therefore, the number of electrons accumulated in the p region 43 at the time of resetting decreases according to the number of trapped holes. In the periphery of the connection part 54, an insulating layer 51 is formed, and the connection part 54 is electrically insulated from portions exclusive of the lower electrode 101r and the p region 43.

The p region 45 is electrically connected to the lower electrode 101b via a connection part 53 formed within an opening penetrating through the insulating layer 48, the R photoelectric conversion device, and the insulating layer 59. A hole trapped by the lower electrode 101b recombines with an electron in the p region 45, and therefore, the number of electrons accumulated in the p region 45 at the time of resetting decreases according to the number of trapped holes. In the periphery of the connection part 53, an insulating layer 50 is formed, and the connection part 53 is electrically insulated from portions exclusive of the lower electrode 101b and the p region 45.

The p region 47 is electrically connected to the lower electrode 101g via a connection part 52 formed within an opening penetrating through the insulating film 48, the R photoelectric conversion device, the insulating film 59, the B photoelectric conversion device and the insulating film 63. A hole trapped by the lower electrode 101g recombines with an electron in the p region 47, and therefore, the number of electrons accumulated in the p region 47 at the time of resetting decreases according to the number of trapped holes. In the periphery of the connection part 52, an insulating layer 49 is formed, and the connection part 52 is electrically insulated from portions exclusive of the lower electrode 101g and the p region 47.

The electrons accumulated in the p region 43 are converted into signals according to the charge amount by an MOS circuit (not shown) composed of a p-channel MOS transistor formed within the n region 42; the electrons accumulated in the p region 45 are converted into signals according to the charge amount by an MOS circuit (not shown) composed of a p-channel MOS transistor formed within the n region 44; the electrons accumulated in the p region 47 are converted into signals according to the charge amount by an MOS circuit (not shown) composed of a p-channel MOS transistor formed within the n region 46; and these signals are outputted to the outside of the imaging device 300. Each of the MOS circuits is connected to a signal read-out pad (not shown) by a wiring 55.

Incidentally, instead of MOS circuits, the signal read-out part may be composed of CCD and an amplifier in a fashion similar to that explained in the third embodiment.

As for the photoelectric conversion layer 102b for absorbing B light, for example, it is preferable to use a material which is capable of absorbing at least light having a wavelength of from 400 nm to 500 nm and in which an absorption factor thereof at a peak wavelength in the wavelength region is 50% or more.

As for the photoelectric conversion layer 102g for absorbing G light, for example, it is preferable to use a material which is capable of absorbing at least light having a wavelength of from 500 nm to 600 nm and in which an absorption factor thereof at a peak wavelength in the wavelength region is 50% or more.

As for the photoelectric conversion layer 102r for absorbing R light, for example, it is preferable to use a material which is capable of absorbing at least light having a wavelength of from 600 nm to 700 nm and in which an absorption factor thereof at a peak wavelength in the wavelength region is 50% or more.

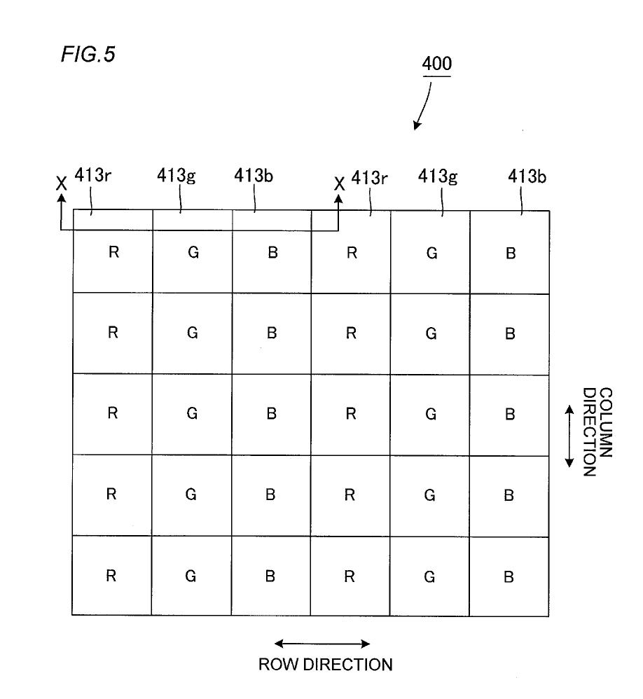

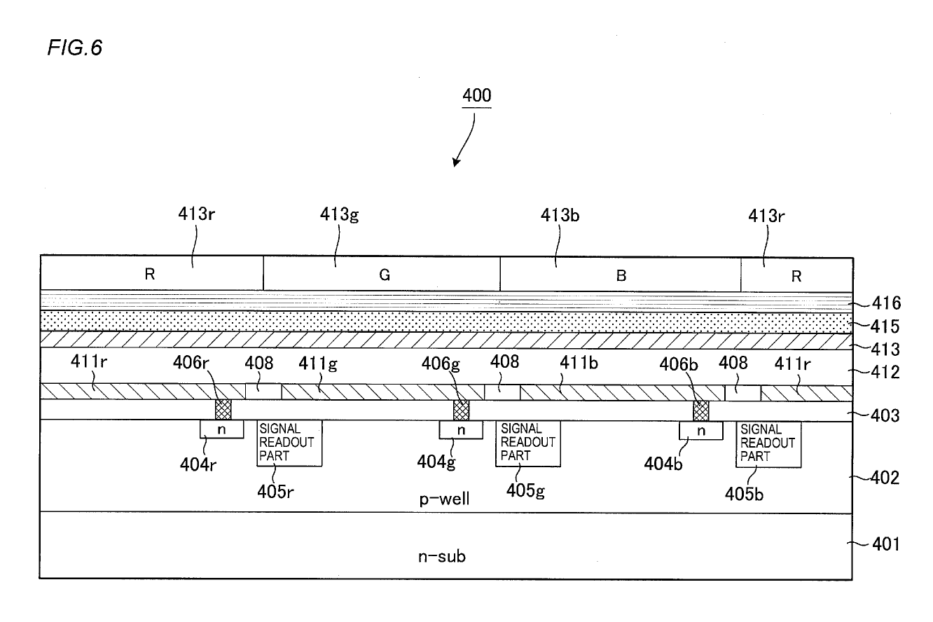

FIG. 5 is a schematic partial surface view of an imaging device 400 according to a fifth embodiment according to the invention, and FIG. 6 is a schematic cross-sectional view of an X-X line of FIG. 5.

A p-well layer 402 is formed on an n-type silicon substrate 401. In the following, the n-type silicon substrate 401 and the p-well layer 402 are collectively referred to as a semiconductor substrate. In the row direction (see FIG. 6) and the column direction (see FIG. 6) crossing with the row direction at right angles on the same plane above the semiconductor substrate, three kinds of color filters inclusive of a color filter 413r mainly transmitting R light therethrough, a color filter 413g mainly transmitting G light therethrough, and a color filter 413b mainly transmitting B light therethrough are each numerously arrayed. Each of the color filters 413r, 413g and 413b can be manufactured using a known material.

As for the array of the color filters 413r, 413g and 413b, a color filter array used in known single-plate solid-state imaging devices (for example, Bayer array, longitudinal stripe, and lateral stripe) can be adopted.

In the p-well layer 402 under the color filters 413r, 413g and 413b, high-density n⁺ regions 404r, 404g and 404b are formed, respectively, and signal read-out parts 405r, 405g and 405b are formed adjacent to the n⁺ regions 404r, 404g and 404b, respectively. A charge according to the incident light amount generated in a photoelectric conversion layer 412 as described later is accumulated in each of the n⁺ regions 404r, 404g and 404b.

An insulating layer 403 is stacked on the surface of the p-well layer 402, and pixel electrode (lower electrode) layers 411r, 411g and 411b corresponding to the n⁺ regions 404r, 404g and 404b, respectively are formed on the insulating layer 403. An insulating layer 408 is provided between the pixel electrodes 411r and 411g, between the pixel electrodes 411g and 411b, and between the pixel electrodes 411b and 411r, respectively. The pixel electrodes 411r and 411g, the pixel electrodes 411g and 411b, and the pixel electrodes 411b and 411r are separated from each other corresponding to the color filters 413r, 413g and 413b, respectively.

The photoelectric conversion film 412 in a one-sheet configuration shared in common among the color filters 413r, 413g and 413b is formed on each of the transparent electrodes 411r, 411g and 411b.

An upper electrode 413 in a one-sheet configuration shared in common among the color filters 413r, 413g and 413b is formed on the photoelectric conversion film 412; a transparent insulating layer 415 and a transparent flat layer 416 are formed on the upper electrode 413; and the color filters 413r, 413g and 413b are stacked thereon.

A photoelectric conversion device corresponding to the color filter 413r is formed by the lower electrode 411r, the upper electrode 413 opposing it, and a part of the photoelectric conversion film 412 sandwiched therebetween. This photoelectric conversion device serves as an R photoelectric conversion device.

A photoelectric conversion device corresponding to the color filter 413g is formed by the lower electrode 411g, the upper electrode 413 opposing it, and a part of the photoelectric conversion film 412 sandwiched therebetween. This photoelectric conversion device serves as a G photoelectric conversion device.

A photoelectric conversion device corresponding to the color filter 413b is formed by the lower electrode 411b, the upper electrode 413 opposing it, and a part of the photoelectric conversion film 412 sandwiched therebetween. This photoelectric conversion device serves as a B photoelectric conversion device.

The respective lower electrodes 411r, 411g and 411b and the corresponding n⁺ regions 404r, 404g and 404b are electrically connected to each other by contact parts 406r, 406g and 406b formed within an opening bored in the insulating layer 403. Each of the contact parts 406r, 406g and 406b is, for example, formed of a metal such as aluminum.

Incidentally, in order to prevent occurrence of the matter that light which has transmitted through the photoelectric conversion layer 412 comes into each of the n⁺ regions 404r, 404g and 404b, it is preferable to provide a light-shielding layer above each of the n⁺ regions 404r, 404g and 404b. Each of the lower electrodes 411r, 411g and 411b may also be made to serve a light-shielding layer as an opaque electrode layer or an electrode layer having a high reflectance, and the insulating layer 408 for separating the lower electrodes from each other may be made of an opaque material or a reflective material.

In such a configuration, when light from a subject comes into the imaging device 400 in a state where a bias voltage is impressed between each of the pixel electrodes 411r, 411g and 411b and the counter electrode (upper electrode) 413, the light which has passed through the red filter 413r comes onto the pixel electrode 411r within the photoelectric conversion layer 412, thereby generating a charge. This charge moves to the corresponding n⁺ region 404r through the contact part 406r, and a charge according to the amount of the red incident light is accumulated in the n⁺ region (charge accumulating region) 404r.

Similarly, the light which has passed through the green filter 413g comes onto the pixel electrode 411g within the photoelectric conversion layer 412, thereby generating a charge. This charge moves to the corresponding n⁺ region 404g through the contact part 406g, and a charge according to the amount of the green incident light is accumulated in the n⁺ region (charge accumulating region) 404g.

Similarly, the light which has passed through the blue filter 413b comes onto the pixel electrode 411b within the photoelectric conversion layer 412, thereby generating a charge. This charge moves to the corresponding n⁺ region 404b through the contact part 406b, and a charge according to the amount of the blue incident light is accumulated in the n⁺ region (charge accumulating region) 404b.

Signals according to the charges accumulated in the charge accumulating regions 404r, 404g and 404b are red out to the outside of the imaging device 400 by the adjacent signal read-out parts 405r, 405g and 405b. Similar to the foregoing embodiments, each of the signal read-out parts 405r, 405g and 405b may be a CMOS circuit or a CCD circuit.

In this way, according to the imaging device 400 according to the present embodiment, it is possible to obtain a color image. However, the photoelectric conversion device becomes thin, so that resolution of the imaged image can be enhanced, and a false color can also be reduced. In addition, an aperture ratio can be made large irrespective of the signal read-out circuit to be provided on the semiconductor substrate, and therefore, it becomes possible to contrive to achieve high sensitivity. Furthermore, it is possible to omit a microlens which is used in the conventional CCD type or CMOS type image sensors, and therefore, there is brought an effect for reducing the number of components and reducing manufacturing steps.

The organic photoelectric conversion layer 412 which is used in the present embodiment is required to have a maximum absorption wavelength in the green light wavelength region and have an absorption region over the entire visible light, but this can be realized by selecting and using the foregoing materials.

### EXAMPLES

Examples and Embodiments of the invention are hereunder described, but it should not be construed that the invention is limited thereto.

Absorption characteristics of compounds in all of the following chloroform dilute solutions were measured in the following manner. A solution of 2×10⁻⁵ M (mol/L) was prepared using commercially available chloroform, and a transmission absorption spectrum thereof was measured using a cell of 1 cm square with UV-3600, manufactured by Shimadzu Corporation. From the absorption spectrum, an absorption maximum wavelength was determined from an absorption maximum value of the longest wave, and an absorbance at the absorption maximum wavelength was divided by a solution concentration to obtain an extinction coefficient.

### Synthesis Example 1

2.5 g of thiobarbituric acid (manufactured by Tokyo Chemical Industry Co., Ltd.) was heat-refluxed in 100 mL of ethanol under nitrogen, to which was then added 3.4 g of N,N′-diphenylformamidine (manufactured by Tokyo Chemical Industry Co., Ltd.), and the mixture was heat-refluxed for 8 hours. After cooling the reaction solution to room temperature, a deposited crystal was filtered and rinsed with ethanol and hexane, thereby obtaining 4.0 g of 5-anilinomethylene-2-thiobarbituric acid. 1.5 g of 5-anilinomethylene-2-thiobarbituric acid, 2.1 g of 3-ethyl-2-methylbenzoxazolium iodide (manufactured by Tokyo Chemical Industry Co., Ltd.), 20 mL of N,N-dimethylacetamide, and 1.9 mL of triethylamine were mixed and then heated at 100° C. for 8 hours. After cooling the reaction mixture to room temperature, the obtained crystal was filtered and then rinsed with acetonitrile, water, and isopropanol, thereby obtaining 1.5 g of Compound 1. As for absorption characteristics of a chloroform dilute solution of Compound 1, the absorption maximum wavelength was 464 nm, and the extinction coefficient was 107,000 M⁻¹cm⁻¹.

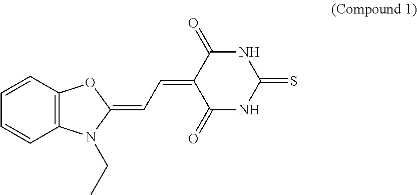 [SMILES: CCN1/C(=C/C=C2C(=O)NC(=S)NC2=O)Oc2ccccc21]

### Synthesis Example 2

Compound 2 was synthesized in the same manner as that in Synthesis Example 1, except for replacing the 3-ethyl-2-methylbenzoxazolium iodide with an equal mole of 5,6-dichloro-1,3-diethyl-2-methylbenzoxazolium iodide (manufactured by Aldrich). As for absorption characteristics of a chloroform dilute solution of Compound 2, the absorption maximum wavelength was 461 nm, and the extinction coefficient was 73,000 M⁻¹cm⁻¹.

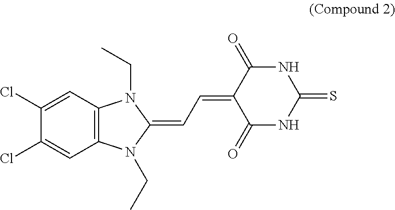 [SMILES: CCN1C(=CC=C2C(=O)NC(=S)NC2=O)N(CC)c2cc(Cl)c(Cl)cc21]

### Synthesis Example 3

Compound 3 was synthesized in the same manner as that in Synthesis Example 1, except for replacing the thiobarbituric acid with an equal mole of 1,3-diethyl-2-thiobarbituric acid (manufactured by Aldrich) and also replacing the 3-ethyl-2-methylbenzoxazolium iodide with an equal mole of 1,2,3,3-tetramethylindolenium iodide (manufactured by Tokyo Chemical Industry Co., Ltd.). As for absorption characteristics of a chloroform dilute solution of Compound 3, the absorption maximum wavelength was 494 nm, and the extinction coefficient was 114,000 M⁻¹cm⁻¹.

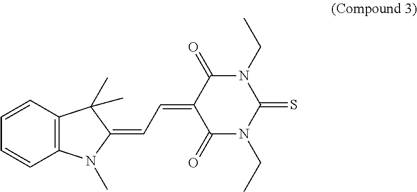 [SMILES: CCN1C(=O)C(=C/C=C2/N(C)c3ccccc3C2(C)C)C(=O)N(CC)C1=S]

### Synthesis Example 4

Compound 4 was synthesized in the same manner as that in Synthesis Example 1, except for replacing the thiobarbituric acid with an equal mole of 1,3-diethyl-2-thiobarbituric acid (manufactured by Aldrich). As for absorption characteristics of a chloroform dilute solution of Compound 4, the absorption maximum wavelength was 469 nm, and the extinction coefficient was 156,0001M⁻¹cm⁻¹.

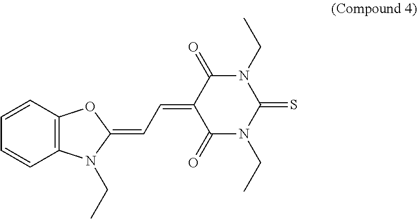 [SMILES: CCN1C(=O)C(=C/C=C2\Oc3ccccc3N2CC)C(=O)N(CC)C1=S]

### Synthesis Example 5

Compound 5 was synthesized in the same manner as that in Synthesis Example 1, except for replacing the 3-ethyl-2-methylbenzoxazolium iodide with an equal mole of 1,2,3,3-tetramethylindolenium iodide (manufactured by Tokyo Chemical Industry Co., Ltd.). As for absorption characteristics of a chloroform dilute solution of Compound 5, the absorption maximum wavelength was 490 nm, and the extinction coefficient was 114,000 M⁻¹cm⁻¹.

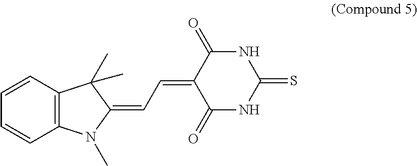 [SMILES: CN1/C(=C/C=C2C(=O)NC(=S)NC2=O)C(C)(C)c2ccccc21]

### Synthesis Example 6

Compound 6 was synthesized in the same manner as that in Synthesis Example 1, except for replacing the thiobarbituric acid with an equal mole of 1-carboxymethyl-3-methyl-barturic acid (obtained through a reaction of N-methyl-N′-carboxymethylurea which can be synthesized according to the usual way, with malonic acid and acetic anhydride in acetic acid). As for absorption characteristics of a chloroform dilute solution of Compound 6, the absorption maximum wavelength was 443 nm, and the extinction coefficient was 84,000 M⁻¹cm⁻¹

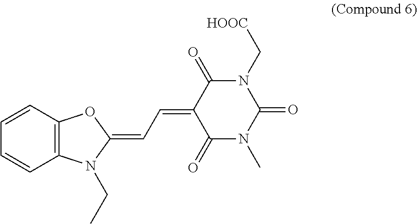 [SMILES: CCN1/C(=C/C=C2\C(=O)N(C)C(=O)N(CC(=O)O)C2=O)Oc2ccccc21]

### Example 1

On a glass substrate, amorphous ITO was deposited in a thickness of 30 nm by a sputtering method to form a lower electrode, and thereafter, Compound 10 was deposited in a thickness of 90 nm by a vacuum heat vapor deposition method while setting up the substrate temperature at 25° C., thereby forming an electron blocking layer. Compound 1 was further deposited in a layer thickness of 170 nm thereon by a vacuum heat vapor deposition method while setting up the substrate temperature at 25° C., thereby forming a photoelectric conversion layer. Incidentally, the vacuum vapor deposition of the photoelectric conversion layer was carried out at a degree of vacuum of not more than 4×10⁻⁴ Pa. Silicon oxide (SiO) was further deposited in a layer thickness of 40 nm thereon by a vacuum heat vapor deposition method while setting up the substrate temperature at 25° C., thereby forming a hole blocking layer. Amorphous ITO as an upper electrode was further deposited in a thickness of 8 nm thereon by a sputtering method, thereby forming a transparent electrically conductive layer, followed by sealing in a glass tube. There was thus fabricated a photoelectric conversion device.

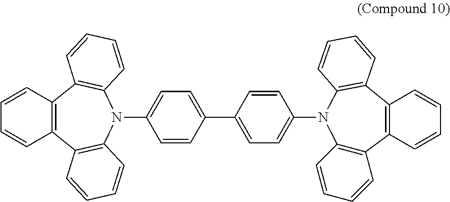 [SMILES: c1ccc2c(c1)-c1ccccc1N(c1ccc(-c3ccc(N4c5ccccc5-c5ccccc5-c5ccccc54)cc3)cc1)c1ccccc1-2]

### Examples 2 to 6

Devices of Examples 2 to 6 were fabricated in the same manner as that in Example 1, except for changing the material and layer thickness of the photoelectric conversion layer as shown in Table 1.

### Comparative Example 1

A device of Comparative Example 1 was fabricated in the same manner as that in Example 1, except for changing the material and layer thickness of the photoelectric conversion layer as shown in Table 1.

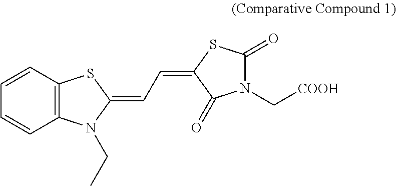 [SMILES: CCN1/C(=C/C=C2/SC(=O)N(CC(=O)O)C2=O)Sc2ccccc21]

As for absorption characteristics of a chloroform dilute solution of Comparative Compound 1, the absorption maximum wavelength was 520 nm, and the extinction coefficient was 91,000 M⁻¹cm⁻¹.

### Comparative Example 2

A device was fabricated by reference to Example 3 in JP-A-2006-86160. As for a configuration of the device in Comparative Example 2, the electron blocking layer and the hole blocking layer are not provided; and ITO is deposited in a thickness of 50 nm (lower electrode), Compound 6 is deposited in a thickness of 50 nm (photoelectric conversion layer), and gold is deposited in a thickness of 20 nm (upper electrode).

### [Evaluation]

Each of the obtained devices was evaluated as a photoelectric conversion device. In the device of Comparative Example 1, an electric field strength at which an external quantum efficiency (efficiency for converting an input photon into an output electron) of the photoelectric conversion at 550 nm reached 15% was determined, and in the devices of Examples 1 to 6 and Comparative Example 2, the test was carried out by impressing the same electric field intensity. At that time, the electric field intensity was 1×10⁵ V/cm or more and not more than 1×10⁶ V/cm. The external quantum efficiency was determined by irradiating B light (450 nm) and dividing the number of output electrons by the number of input photons. A G/B color mixing ratio was determined by dividing the external quantum efficiency at the time of irradiating G light (550 nm) by the external quantum efficiency at the time of irradiating B light. An R/B color mixing ratio was determined by dividing the external quantum efficiency at the time of irradiating R light (640 nm) by the external quantum efficiency at the time of irradiating B light. A dark current was measured by impressing the foregoing electric field intensity to the device in a dark room.

As for a thin film absorption maximum wavelength, a thin film was separately formed to have a thickness of from 80 to 130 nm using each of Compounds 1 to 6 and Comparative Compound 1 on a glass substrate in the same operation as that in the formation of photoelectric conversion layer of the Examples by means of vacuum heat vapor deposition, and an absorption maximum wavelength that is the longest wave was determined from a transmission spectrum thereof.

TABLE 1

| | | | External | | | | |
|---|---|---|---|---|---|---|---|
| | | Layer | quantum | | | | |
| | | thickness of | efficiency | | | | Thin film |
| | | photoelectric | relative to B | | | | absorption |
| Photoelectric | | conversion | light | G/B color | R/B color | Dark current | maximum |
| conversion | | layer | (Relative | mixing ratio | mixing ratio | (Relative | wavelength |
| device | Compound | (nm) | value) | (%) | (%) | value) | (nm) |
| Example 1 | Compound 1 | 170 | 5.8 | <1 | <1 | 0.3 | 485 |
| Example 2 | Compound 2 | 130 | 3.8 | <1 | <1 | 0.7 | 480 |
| Example 3 | Compound 3 | 150 | 3.1 | 8 | <1 | 0.5 | 510 |
| Example 4 | Compound 4 | 200 | 2.9 | <1 | <1 | 0.7 | 480 |
| Example 5 | Compound 5 | 100 | 5.0 | 9 | <1 | 0.7 | 505 |
| Example 6 | Compound 6 | 130 | 1.9 | <1 | <1 | 0.8 | 460 |
| Comparative | Comparative | 100 | 1.0 | 150 | 10 | 1.0 | 560 |
| Example 1 | Compound 1 | | | | | | |
| Comparative | Compound 6 | 150 | 1.0 | <1 | <1 | >100 | 457 |
| Example 2 | | | | | | | |

It is noted that in comparison with Comparative Example 1, Examples 1 to 6 are high in terms of the external quantum efficiency relative to the B light, in particular, Examples 1 to 5 are high in terms of the external quantum efficiency. Furthermore, it is noted that Examples 1 to 6 are low in terms of the G/B color mixing ratio and the R/B color mixing ratio, in particular, Examples 1, 2, 4 and 6 in which the thin film absorption maximum wavelength is not more than 500 nm are especially low in terms of the G/B color mixing ratio. Furthermore, it is noted that Examples 1 to 6 are low in terms of the dark current.

It is noted that in comparison with Comparative Example 2, Examples 1 to 6 are high in terms of the external quantum efficiency relative to the B light, in particular, Examples 1 to 5 are high in terms of the external quantum efficiency. Furthermore, it is noted that Examples 1 to 6 are extremely low in terms of the dark current.

Furthermore, the same imaging device as the form shown in FIG. 2 was fabricated. That is, after depositing amorphous ITO in a thickness of 30 nm on a CMOS substrate by a sputtering method, patterning was carried out by means of photolithography in such a manner that one pixel was present on each photodiode (PD) on the CMOS substrate, thereby forming a lower electrode, and thereafter, the same procedures as those subsequent to the deposition of an electron blocking material were followed to fabricate the imaging device. The evaluation thereof was carried out in the same manner. As a result, the same results as those in Table 1 were obtained. Thus, it was noted that even in the imaging device, the devices on the basis of the Examples of the invention are high in terms of the external quantum efficiency and low in terms of the G/B color mixing ratio, the R/B color mixing ratio, and the dark current.

### INDUSTRIAL APPLICABILITY

According to the invention, a photoelectric conversion device exhibiting high photoelectric conversion efficiency (high sensitivity) and low dark current and having high photoselection, an imaging device, and a method for driving a photoelectric conversion device are obtainable.

While the invention has been described in detail and with reference to specific embodiments thereof, it will be apparent to one skilled in the art that various changes and modifications can be made therein without departing from the spirit and scope thereof.

The present application is based on a Japanese patent application filed on May 31, 2010 (Japanese Patent Application No. 2010-125325), the contents of which are incorporated herein by reference.

### EXPLANATIONS OF LETTERS OR NUMERALS

11, 101: Lower electrode (pixel electrode layer)
12, 102: Organic photoelectric conversion layer
15, 104: Upper electrode (counter electrode layer)
16A: Electron blocking layer
16B: Hole blocking layer
100, 200, 300, 400: Imaging device

What is claimed is:

1. A photoelectric conversion device comprising, in the following order: a first electrode; an electron blocking layer; a photoelectric conversion layer containing a merocyanine dye; a hole blocking layer; and a transparent electrode as a second electrode, wherein an absorption maximum wavelength in a thin film absorption spectrum of the photoelectric conversion layer containing a merocyanine dye falls within a range of from 400 to 520 nm.

2. The photoelectric conversion device according to claim 1, wherein the merocyanine dye is represented by the following general formula (1): 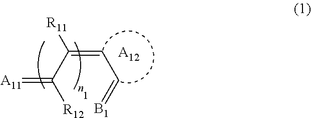
wherein A₁₁ represents a heterocyclic ring; n₁ represents an integer of from 0 to 2; A₁₂ represents a heterocyclic ring containing an sp2 carbon atom and a carbon atom of a carbonyl group or a thiocarbonyl group; each of R₁₁ and R₁₂ independently represents a hydrogen atom or a substituent; and B₁ represents an oxygen atom or a sulfur atom.

3. The photoelectric conversion device according to claim 2, wherein A₁₂ in the general formula (1) is a 6-membered heterocyclic ring.

4. The photoelectric conversion device according to claim 2, wherein an absorption maximum wavelength of the merocyanine dye represented by the general formula (1) in a solution state in a visible region falls within a range of from 400 to 500 nm.

5. The photoelectric conversion device according to claim 3, wherein an absorption maximum wavelength of the merocyanine dye represented by the general formula (1) in a solution state in a visible region falls within a range of from 400 to 500 nm.

6. The photoelectric conversion device according claim 1, wherein the first electrode is a transparent electrode.

7. The photoelectric conversion device according claim 2, wherein the first electrode is a transparent electrode.

8. The photoelectric conversion device according claim 3, wherein the first electrode is a transparent electrode.

9. The photoelectric conversion device according claim 4, wherein the first electrode is a transparent electrode.

10. The photoelectric conversion device according to claim 1, wherein the electron blocking layer contains an organic electron blocking material.

11. The photoelectric conversion device according to claim 2 wherein the electron blocking layer contains an organic electron blocking material.

12. The photoelectric conversion device according to claim 3 wherein the electron blocking layer contains an organic electron blocking material.

13. The photoelectric conversion device according to claim 4 wherein the electron blocking layer contains an organic electron blocking material.

14. The photoelectric conversion device according to claim 1, wherein the hole blocking layer contains an inorganic material.

15. The photoelectric conversion device according to claim 2, wherein the hole blocking layer contains an inorganic material.

16. The photoelectric conversion device according to claim 3, wherein the hole blocking layer contains an inorganic material.

17. The photoelectric conversion device according to claim 4, wherein the hole blocking layer contains an inorganic material.

18. An imaging device comprising the photoelectric conversion device according to claim 1.

19. A method for driving the photoelectric conversion device according to claim 1, which comprises applying an electric field of from 1×10⁻⁴ V/cm to 1×10⁷ V/cm between the first and second electrodes of the photoelectric conversion device.
